(19) United States
(12) Patent Application Publication
(10) Pub. No.: US 2026/0271178 A1
(43) Pub. Date: Sep. 10, 2026

(54) MULTILAYER SUBSTRATE, METHOD OF MANUFACTURING MULTILAYER SUBSTRATE, AND ELECTRONIC DEVICE

(71) Applicant: Murata Manufacturing Co., Ltd., Nagaokakyo-shi (JP)

(72) Inventors: Hiroki YAMADA, Nagaokakyo-shi (JP); Keiichi ICHIKAWA, Nagaokakyo-shi (JP); Naoki GOUCHI, Nagaokakyo-shi (JP); Nobuo IKEMOTO, Nagaokakyo-shi (JP); Takahiro BABA, Nagaokakyo-shi (JP)

(21) Appl. No.: 19/662,115

(22) Filed: Apr. 29, 2026

Related U.S. Application Data
(63) Continuation of application No. PCT/JP2024/038490, filed on Oct. 29, 2024.

(30) Foreign Application Priority Data
Nov. 10, 2023 (JP) 2023-192232

(51) Int. Cl. H05K 1/02; H05K 1/03; H05K 3/46

(52) U.S. Cl. CPC H05K 1/0219; H05K 1/0313; H05K 3/46; H05K 2201/0129; H05K 2201/10098; H05K 2203/1105

(57) ABSTRACT

A multilayer substrate includes base material layers and a conductor pattern stacked on each other, first and second portions in which a thickness between front and back surfaces that face each other is constant or approximately constant, the second portion being continuous with the first portion. The front surface of the first portion is at least one convex curved surface, the back surface of the first portion is a concave curved surface that faces the at least one convex curved surface, the front and back surfaces of the second portion are planes, each of the base material layers is continuous from the first portion to the second portion and at least a portion of the conductor pattern is continuous from the first portion to the second portion in an inside of the multilayer substrate.

### CROSS REFERENCE TO RELATED APPLICATIONS

This application claims the benefit of priority to Japanese Patent Application No. 2023-192232 filed on Nov. 10, 2023 and is a Continuation Application of PCT Application No. PCT/JP2024/038490 filed on Oct. 29, 2024. The entire contents of each application are hereby incorporated herein by reference.

### BACKGROUND OF THE INVENTION

### 1. Field of the Invention

The present invention relates to multilayer substrates each configured by stacking a plurality of base material layers, methods of manufacturing such multilayer substrates, and electronic devices including such multilayer substrates.

### 2. Description of the Related Art

Japanese Unexamined Patent Application Publication No. 2004-82564 discloses a support of an electronic device that utilizes characteristics of a thermoplastic liquid crystal polymer and that has a stepwise difference. For example, an electronic device in which a support constituted by a film or constituted by a laminate structure having films is formed with a stepwise difference having a gradient by a drawing process is shown.

### SUMMARY OF THE INVENTION

Although the support of the electronic device disclosed in Japanese Unexamined Patent Application Publication No. 2004-82564 is made of a three-dimensional thermoplastic liquid crystal polymer, this support is a structure in which a conductor pattern is formed only on that surface layer. Therefore, the degree of freedom in wiring provided in the support is low.

Example embodiments of the present invention provide multilayer substrates each with a high degree of freedom in forming a conductor pattern, methods of manufacturing such multilayer substrates, and electronic devices including such multilayer substrates.

A multilayer substrate as one example of an example embodiment the present disclosure is a multilayer substrate including a plurality of base material layers and a conductor pattern stacked on each other, a first portion and a second portion each of which a thickness between front and back surfaces that face each other is constant or approximately constant, the second portion being continuous with the first portion, the front surface of the first portion is a convex curved surface and the back surface of the first portion is a concave curved surface that faces the convex curved surface and gives the thickness to the multilayer substrate, the front and back surfaces of the second portion are planes, each of the base material layers is continuous from the first portion to the second portion, and at least a portion of the conductor pattern is continuous from the first portion to the second portion in an inside of the multilayer substrate.

A method of manufacturing a multilayer substrate as one example of an example embodiment of the present disclosure is a method of manufacturing a multilayer substrate in which the first portion includes a connection conductor that electrically connects the conductor pattern inside the multilayer substrate, and defines a conductive path in a direction of the stacking, the first portion and the second portion of the multilayer substrate are formed by performing heating and pressing in a state in which base material layers are stacked, and the opening in the direction of the stacking is filled with conductive paste, the heating and pressing is performed, and then the conductive paste as the conductive path is formed.

An electronic device as one example of an example embodiment of the present disclosure is an electronic device including the multilayer substrate and an electronic component inside the first portion or the second portion.

According to example embodiments of the present invention, multilayer substrates each with a high degree of freedom in forming a conductor pattern, methods of manufacturing such multilayer substrates, and electronic devices including such multilayer substrates are obtained.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a perspective view of a multilayer substrate 101 according to a first example embodiment of the present invention.

The upper portion of FIG. 2 is a plan view of the multilayer substrate 101, and the lower portion of FIG. 2 is a cross-sectional view of the multilayer substrate 101 shown in the upper portion of FIG. 2 taken along a dashed-dotted line.

FIG. 3 is a cross-sectional view of a multilayer substrate 102 according to a second example embodiment of the present invention.

FIG. 4 is a cross-sectional view of an electronic device 201 according to a third example embodiment of the present invention.

FIG. 5 is a cross-sectional view of an electronic device 202 according to a fourth example embodiment of the present invention.

FIG. 6 is a cross-sectional view of another electronic device 203 according to the fourth example embodiment of the present invention.

The upper portion of FIG. 7 is a plan view of an electronic device 204 according to a fifth example embodiment, and the lower portion of FIG. 7 is a cross-sectional view of the electronic device 204 taken along a dashed-dotted line shown in the upper portion.

The upper portion of FIG. 8 is a plan view of a multilayer substrate 107 according to a sixth example embodiment of the present invention. The lower portion of FIG. 8 is a cross-sectional view of an electronic device 205 including the multilayer substrate 107 shown in the upper portion of FIG. 8.

FIG. 9 is a plan view of another multilayer substrate 108 according to the sixth example embodiment of the present invention.

FIG. 10 is a cross-sectional view of an electronic device 206 according to a seventh example embodiment that is configured by installing a multilayer substrate 109 on which an electronic component 65 is mounted, on a circuit board 60.

FIG. 11 is a cross-sectional view of an electronic device 207 according to the seventh example embodiment that is configured by installing a multilayer substrate 110 on which an electronic component 66 is mounted, on the circuit board 60.

FIG. 12 is a cross-sectional view of an electronic device 208 according to the seventh example embodiment that is configured by installing a multilayer substrate 111 on which the electronic components 65 and 66 are mounted, on a circuit board 60.

The upper portion of FIG. 13 is a plan view of an electronic device 209 according to an eighth example embodiment, and the lower portion of FIG. 13 is a cross-sectional view of the electronic device 209 taken along a dashed-dotted line in the upper portion of FIG. 13.

The upper portion of FIG. 14 is a plan view of another multilayer substrate 113 according to the eighth example embodiment, and the lower portion of FIG. 14 is a cross-sectional view of the multilayer substrate 113 taken along a dashed-dotted line in the upper portion of FIG. 14.

The upper portion of FIG. 15 is a plan view of an electronic device 210 according to a ninth example embodiment of the present invention. The lower portion of FIG. 15 is a cross-sectional view taken along a dashed-dotted line in the upper portion of FIG. 15.

The upper portion of FIG. 16 is a plan view of another electronic device 211 according to the ninth example embodiment of the present invention. The lower portion of FIG. 16 is a cross-sectional view taken along a dashed-dotted line in the upper portion of FIG. 16.

The upper portion of FIG. 17 is a plan view of a multilayer substrate 115 according to a tenth example embodiment of the present invention. The lower portion of FIG. 17 is a cross-sectional view taken along a dashed-dotted line in the upper portion of FIG. 17.

FIG. 18 is a perspective view of a multilayer substrate 116 according to an eleventh example embodiment of the present invention.

The upper portion of FIG. 19 is a plan view of an electronic device 212 including the multilayer substrate 116, and the lower portion of FIG. 19 is a cross-sectional view taken along a dashed-dotted line shown in the upper portion of FIG. 19.

FIG. 20 is a perspective view of a multilayer substrate 117A according to a twelfth example embodiment of the present invention.

The upper portion of FIG. 21 is a cross-sectional view taken along a dashed-dotted line in FIG. 20.

FIG. 22 is a perspective view of another multilayer substrate 117B according to the twelfth example embodiment of the present invention.

FIG. 23 is a cross-sectional view taken along a dashed-dotted line in FIG. 22.

FIG. 24 is a perspective view of an electronic device 213 configured by a multilayer substrate 118 according to a thirteenth example embodiment and an electronic component 62 mounted on the multilayer substrate.

The upper portion of FIG. 25 is a perspective view of an electronic device 214 configured by a multilayer substrate 119 according to a fourteenth example embodiment and the electronic component 62 mounted on the multilayer substrate. The lower portion of FIG. 25 is a cross-sectional view taken along a dashed-dotted line in the upper portion of FIG. 25.

FIG. 26 is a view showing another multilayer substrate 120 according to the fourteenth example embodiment of the present invention.

The upper portion of FIG. 27 is a perspective view of a multilayer substrate 121 according to a fifteenth example embodiment, and the lower portion of FIG. 27 is a vertical cross-sectional view at a position shown by a dashed-dotted line of the upper portion of FIG. 27.

FIG. 28 shows each of cross-sectional views of a multilayer substrate according to a sixteenth example embodiment of the present invention.

FIG. 29 shows each of cross-sectional views of the multilayer substrate according to the sixteenth example embodiment of the present invention.

FIG. 30 is a cross-sectional view of the multilayer substrate according to the sixteenth example embodiment, and is an example of a multilayer substrate including conductor patterns 81 and 82 as signal lines, and conductor patterns 49A and 49B as two-layer ground conductor layers that interpose the conductor patterns in a stacking direction.

FIG. 31 is a cross-sectional view of the multilayer substrate according to the sixteenth example embodiment, and is a view showing some examples of a position at which a conductor pattern as a ground conductor layer is formed.

FIG. 32 is a cross-sectional view of a main portion of an electronic device 215 shown in a seventeenth example embodiment of the present invention.

The upper portion of FIG. 33 is a perspective view of an electronic device 216 according to an eighteenth example embodiment, the middle portion of FIG. 33 is a vertical cross-sectional view of a multilayer substrate 122 taken along line X-X of the upper portion of FIG. 33, and the lower portion of FIG. 33 is a vertical cross-sectional view of the multilayer substrate 122 taken along line Y-Y of the upper portion of FIG. 33.

FIG. 34 shows plan views of several other multilayer substrates according to an eighteenth example embodiment of the present invention.

The upper portion and lower portion of FIG. 35 are cross-sectional views of the other multilayer substrates according to the eighteenth example embodiment of the present invention.

FIG. 36 shows cross-sectional views of several other multilayer substrates according to the eighteenth example embodiment of the present invention.

The upper portion of FIG. 37 is a plan view of an electronic device 217 including a multilayer substrate 123 and electronic components 62 and 65, and the lower portion of FIG. 37 is a vertical cross-sectional view taken along a dashed-dotted line in the upper portion.

The upper portion of FIG. 38 is a partial cross-sectional view of the electronic device 217. The lower portion of FIG. 38 is a transverse cross-sectional view taken along a dashed-dotted line in the upper portion of FIG. 38.

FIG. 39 is a plan view of another electronic device according to a nineteenth example embodiment of the present invention.

The upper portion of FIG. 40 is a plan view of an electronic device 218 including a multilayer substrate 124 and the electronic component 62, and the lower portion of FIG. 40 is a vertical cross-sectional view taken along a dashed-dotted line in the upper portion.

The upper portion of FIG. 41 is a partial cross-sectional view of the electronic device 218. The middle portion of FIG. 41 is a transverse cross-sectional view taken along a dashed-dotted line in the upper portion in the drawing of the upper portion of FIG. 41, and the lower portion of FIG. 41 is a transverse cross-sectional view taken along a dashed-dotted line in the lower portion in the drawing of the upper portion of FIG. 41.

FIG. 42 shows perspective views of electronic devices 219 and 220 according to a twenty-first example embodiment of the present invention.

The upper portion of FIG. 43 is a partial cross-sectional view of a first portion 10 of the electronic device 219 shown in the upper portion of FIG. 42, and the lower portion of FIG. 43 is a partial cross-sectional view of a first portion 10 of the electronic device 220 shown in the lower portion of FIG. 42.

The upper portion and lower portion of FIG. 44 each are a perspective view and front view of a multilayer substrate 125 according to a twenty-second example embodiment of the present invention.

The upper portion, middle portion, and lower portion of FIG. 45 each are a plan view, bottom view, and side view of the multilayer substrate 125.

The upper portion and lower portion of FIG. 46 each are perspective views as viewed from an upper side and bottom side of a multilayer substrate 126 according to a twenty-third example embodiment of the present invention.

The upper portion, middle portion, and lower portion of FIG. 47 each are a plan view, bottom view, and side view of the multilayer substrate 126.

FIG. 48 is a cross-sectional view of an electronic device 221 according to a twenty-fourth example embodiment of the present invention.

The upper portion and lower portion of FIG. 49 each are perspective views as viewed from an upper side and bottom side of a multilayer substrate 128 according to a twenty-fifth example embodiment of the present invention.

The upper portion, middle portion, and lower portion of FIG. 50 each are a front view, right side view, and left side view of the multilayer substrate 128.

FIG. 51 is a plan view showing the multilayer substrate 128 arranged in a housing 73.

FIG. 52 shows an example of a plan view of a multilayer substrate, when viewed in a projecting direction of the multilayer substrate by presence of a convex curved surface and concave curved surface of the multilayer substrate.

### DETAILED DESCRIPTION OF THE EXAMPLE EMBODIMENTS

Hereinafter, a plurality of example embodiments of the present invention will be described with reference to the drawings and several specific examples. In the drawings, components and elements assigned with the same reference numerals or symbols will represent the same or corresponding components and elements. While the plurality of example embodiments are divided into a group of example embodiments and described for the sake of convenience in consideration of ease of description or understanding of main points, elements described in different example embodiments are able to be partially rearranged and combined with each other. In second and subsequent example embodiments, a description of matters common to the first example embodiment will be omitted and only different points will be described. In particular, the same or substantially the same advantageous functions and effects by the same configurations will not be described one by one for each example embodiment.

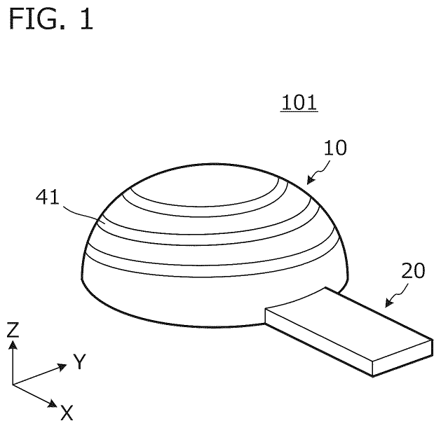

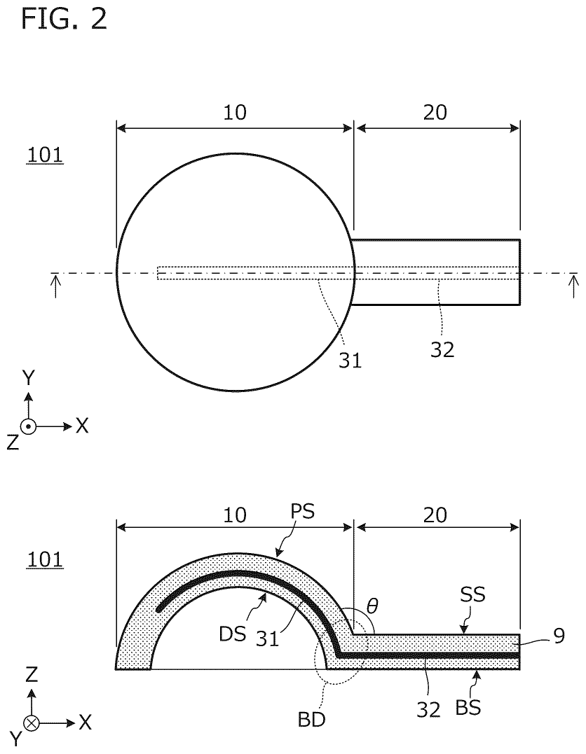

A first example embodiment shows one example of a multilayer substrate. FIG. 1 is a perspective view of a multilayer substrate 101 according to the first example embodiment. The upper portion of FIG. 2 is a plan view of the multilayer substrate 101, and the lower portion of FIG. 2 is a cross-sectional view of the multilayer substrate 101 shown in the upper portion of FIG. 2 taken along a dashed-dotted line.

The multilayer substrate 101 is a multilayer substrate in which a plurality of base material layers 9 are stacked. In the cross-sectional view shown in the lower portion of FIG. 2, each of the base material layers is integrated, so that a line between adjacent base material layers does not appear. Therefore, the base material layer 9 in the drawing is not a symbol that indicates a single base material layer but a single symbol that indicates a plurality of base material layers. The same applies to other drawings shown below.

The multilayer substrate 101 includes a first portion 10 and a second portion 20 each of which a thickness between front and back surfaces that face each other is constant or approximately constant, the second portion being continuous with the first portion 10.

The front surface of the first portion 10 is at least one convex curved surface PS, and the back surface of the first portion 10 is a concave curved surface DS that faces the convex curved surface PS. The front surface SS and back surface BS of the second portion 20 are planes.

The convex curved surface PS is not a surface that curves around an axis orthogonal to a projecting direction. In the example shown in FIG. 1 and FIG. 2, a Z-axis direction is the projecting direction. The surface that curves around a Y-axis, for example, orthogonal to this projecting direction is a cylindrical surface. In the example shown in FIG. 1 and FIG. 2, the convex curved surface PS is not a cylindrical surface but a spherical surface.

The shape of the convex curved surface PS, when being expressed in an alternative way, can be expressed as a curve drawn in a cross-section in a plane configured by two axes and a curve drawn also in a cross-section in a plane configured by two other axes, among three orthogonal axes with the projecting direction of the convex curved surface PS as one axis. In FIG. 1 and FIG. 2, when the orientations of the three X, Y, and Z axes are the above-described three orthogonal axes, the cross-section in the X-Y plane of the convex curved surface PS is a circle, the cross-section in the Y-Z plane of the convex curved surface PS is an arc, and the cross-section in the X-Z plane of the convex curved surface PS is an arc. In short, the cross-section in any two-axis plane does not draw a straight line.

The concave curved surface DS faces the convex curved surface PS in a relationship that maintains the thickness of the multilayer substrate.

Each of the base material layers 9 is continuous from the first portion 10 to the second portion 20. In addition, the conductor pattern 31 inside the first portion 10 and the conductor pattern 32 inside the second portion 20 are continuous.

In FIG. 2, although, in the cross-section passing through a boundary BD between the first portion 10 and the second portion 20, an angle defined by the first portion 10 and the second portion 20 is different corresponding to the position of the cross-section, in a plurality of cross-sections passing through a boundary BD between the first portion 10 and the second portion 20, the minimum angle θ defined by the first portion 10 and the second portion 20 in the boundary BD is an obtuse angle. With this structure, even when the boundary BD between the first portion 10 and the second portion 20 is bent, breakage in the boundary BD, in particular, of the conductor patterns 31 and 32 is significantly reduced.

It is to be noted that a bent portion (the boundary BD between the first portion 10 and the second portion 20) between the conductor pattern 31 and the conductor pattern 32 may have a shape with chamfered corners or a curved shape. As a result, stress applied to the bent portion between the conductor pattern 31 and the conductor pattern 32 is dispersed, so that the breakage of the bent portion between this conductor pattern 31 and the conductor pattern 32 is more effectively significantly reduced.

In the example shown in FIG. 1, a conductor pattern 41 is formed on a front surface of the first portion of the multilayer substrate 101. This conductor pattern 41 is an antenna radiation element, for example, and is electrically connected to the conductor pattern 31 inside the multilayer substrate 101. Although not shown in FIG. 2, the conductor pattern 41 and the conductor pattern 31 are connected with a connection conductor that forms a conductive path in a direction of stacking of the base material layers 9.

Although FIG. 2 shows an example in which the conductor patterns 31 and 32 are provided inside the multilayer substrate 101, at a location to be used as a transmission line of the conductor patterns 31 and 32, a stripline may be configured by forming a ground conductor layer on the front and back surfaces of the multilayer substrate 101.

It is to be noted that the conductor pattern 41 and the conductor pattern 31 may be electromagnetically coupled to or electrically coupled to each other.

The outer shape as viewed in the projecting direction of the convex curved surface of the first portion 10 has a circular or substantially circular shape. In addition, the outer shape of the second portion 20 as viewed in the projecting direction of the convex curved surface of the first portion 10 has a rectangular or substantially rectangular shape.

In addition, in the example shown in FIG. 1 and FIG. 2, the plane shape of the second portion 20 as viewed in the projecting direction (a Z direction) of the convex curved surface is a shape projecting from a portion of positions surrounding the first portion 10. This second portion 20 may have a shape projecting from all positions surrounding the first portion 10.

The material of the base material layers 9 is, for example, styrene, a polyolefin-based resin such as polyethylene and polypropylene, or a thermoplastic resin such as thermoplastic polyimide and a fluorine-based resin. Accordingly, a shape at the boundary BD between the first portion 10 and the second portion 20 is easily changed.

The multilayer substrate 101 shown above, in a state in which the plurality of base material layers 9 including the base material layers 9 on which the conductor patterns 31 and 32 are formed are stacked, for example, is formed as a multilayer substrate including the first portion 10 and the second portion 20 by simultaneously heating and pressing the whole by a metal mold having a convex curved surface and a metal mold having a concave curved surface.

A second example embodiment shows an example in which a shape of a conductor pattern of a first portion and a structure of a second portion are different from the first example embodiment.

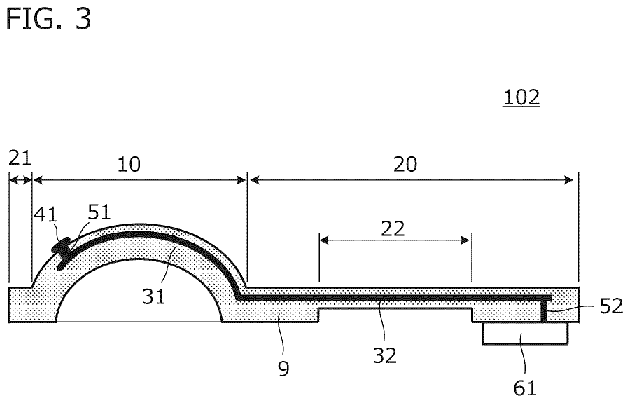

FIG. 3 is a cross-sectional view of a multilayer substrate 102 according to the second example embodiment. The plan view of this multilayer substrate 102 is similar to the multilayer substrate 101 shown in FIG. 1 and FIG. 2.

The multilayer substrate 102 includes a first portion 10 and a second portion 20 each of which a thickness between front and back surfaces that face each other is constant or approximately constant, the second portion being continuous with the first portion 10.

The shape of the second portion 20 is a shape drawn outside from the first portion 10. The first portion 10 includes a circuit portion including base material layers 9 and a conductor pattern. In addition, in the example shown in FIG. 3, a second portion 21 drawn outside from the first portion 10 is provided. In this manner, the second portion may have more than one. In addition, a direction in which the second portion is drawn out from the first portion 10 may be different.

The first portion 10 of the multilayer substrate 102 includes a connection conductor 51 that is electrically connected to a conductor pattern 31 inside the multilayer substrate 102 and forms a conductive path in the direction of the stacking. A conductor pattern 41 is located on a front surface of the first portion 10. The connection conductor 51 electrically connects the conductor pattern 31 and the conductor pattern 41.

The second portion 20 includes a transmission line including the base material layers 9 and a conductor pattern 32. A connection conductor 52 that is electrically connected to this conductor pattern 32 and forms a conductive path in the direction of the stacking is provided near an end portion of the conductor pattern 32.

A connector 61 is installed on the back surface of the second portion 20, and the connection conductor 52 is connected to this connector 61.

The conductor pattern 31 inside the first portion 10 and the conductor pattern 32 inside the second portion 20 are continuous.

The second portion 20 partially has a thin region 22 of the second portion of which the thickness is smaller than the first portion 10. With this structure, bending becomes easy in the thin region 22, and stress applied to the conductor pattern 32 inside the thin region is able to be significantly reduced, so that breakage of the conductor pattern 32 is able to be prevented.

A non-limiting example of a method of manufacturing the multilayer substrate 102 described above is as follows.

First, the first portion 10 and second portion 20 of the multilayer substrate 102 are formed by performing heating and pressing in a state in which the base material layers 9 are stacked.

An opening in the direction of the stacking of the base material layers 9 is filled with conductive paste, and the heating and pressing is performed on the entire stacked body. Accordingly, the conductive paste forms the connection conductor.

A third example embodiment exemplifies an electronic device.

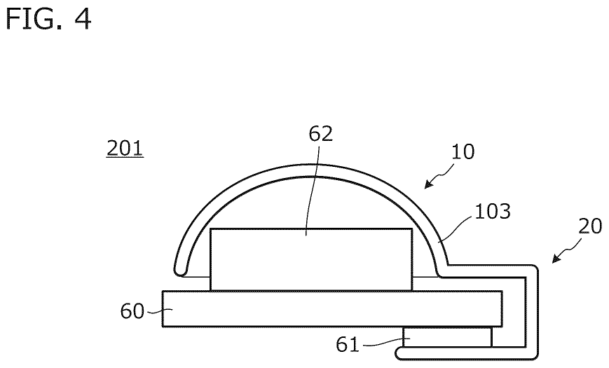

FIG. 4 is a cross-sectional view of an electronic device 201 according to the third example embodiment. This electronic device 201 includes a circuit board 60, an electronic component 62 mounted on this circuit board 60, a multilayer substrate 103, and a connector 61 attached to this multilayer substrate 103. In FIG. 4, prioritizing clarity and visibility of the drawing, illustration of hatching showing a cross-sectional portion is omitted. Although a conductor pattern is formed in the multilayer substrate 103, the conductor pattern is not present at a cross-sectional position in FIG. 4.

The outer shape (the plane shape) of the multilayer substrate 103 as viewed in the projecting direction of the convex curved surface of the first portion 10 has a circular or substantially circular shape. The plane shape of the second portion 20 before bending (or curving) as viewed in the projecting direction of the convex curved surface is a rectangular or substantially rectangular shape projecting from a portion of positions surrounding the first portion 10. Such a rectangular or substantially rectangular portion is bent (curved), which makes the bending (curving) of the second portion 20 easy. It is to be noted that this bent (curved) portion may be a portion corresponding to the thin region 22 in FIG. 3, that is, a portion in which the bending (curving) is easier.

The electronic component 62 is mounted on a portion of the circuit board 60 surrounded by the concave curved surface of the first portion 10 of the multilayer substrate 103. A predetermined conductor pattern is inside the multilayer substrate 103 and, as necessary, on an outer surface.

The second portion 20 of the multilayer substrate 103 is bent (curved) at two locations so as to surround the end portion of the circuit board 60. The circuit of the circuit board 60 and the conductor pattern of the multilayer substrate 103 are electrically connected to each other through the connector 61.

The circuit board 60 or the electronic component 62 mounted on the circuit board is connected to the conductor pattern located at the second portion 20 of the multilayer substrate 103. Alternatively, it is connected to the conductor pattern located at the first portion 10 and second portion 20 of the multilayer substrate 103.

According to the present example embodiment, the first portion 10 of the multilayer substrate 103 is arranged so as to cover the circuit board 60 having a flat plate shape, which makes it possible to form a predetermined space between the first portion 10 of the multilayer substrate 103 and the circuit board 60. In addition, the second portion 20 of the multilayer substrate 103 is bent (curved), so that the second portion 20 is able to reach even at the back surface of the circuit board 60. In this manner, the base material layers 9 are made of a thermoplastic resin, which increases the degree of freedom in processes in manufacturing an electronic device.

A fourth example embodiment exemplifies an electronic device including a multilayer substrate in which a hole is formed in a first portion.

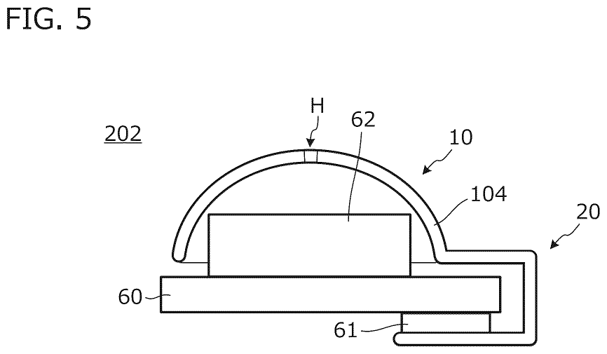

FIG. 5 is a cross-sectional view of an electronic device 202 according to the fourth example embodiment. This electronic device 202 includes a circuit board 60, an electronic component 62 mounted on this circuit board 60, a multilayer substrate 104, and a connector 61 attached to this multilayer substrate 104. In FIG. 5, prioritizing clarity and visibility of the drawing, illustration of hatching showing a cross-sectional portion is omitted. Although a conductor pattern is formed in the multilayer substrate 104, the conductor pattern is not present at a cross-sectional position in FIG. 5.

As with the example shown in FIG. 4, the outer shape (the plane shape) of the multilayer substrate 104 as viewed in the projecting direction of the convex curved surface of the first portion 10 is a circular or substantially circular shape, and the plane shape of the second portion 20 before bending (or curving) has a rectangular or substantially rectangular shape projecting from a portion of positions surrounding the first portion 10.

A predetermined circuit is configured in the circuit board 60. The electronic component 62 is, for example, a MEMS microphone. The circuit board 60 includes a circuit for an audio signal by this MEMS microphone.

A predetermined conductor pattern is inside the multilayer substrate 104 and, as necessary, on an outer surface.

A through hole H is formed in a portion of the multilayer substrate 104. The through hole H is located at a position close to a sound-receiving portion of the electronic component 62 being the MEMS microphone in the example shown in FIG. 5. This through hole H has a sound-collection effect, so that a microphone having a predetermined directivity is able to be configured.

According to the present example embodiment, the electronic component 62 is arranged in a predetermined space between the first portion 10 of the multilayer substrate 104, and the circuit board 60, and the through hole H is provided in the multilayer substrate 104, which enables effective arrangement with the multilayer substrate 104 and the electronic component 62, and more easily miniaturizes the electronic device 202.

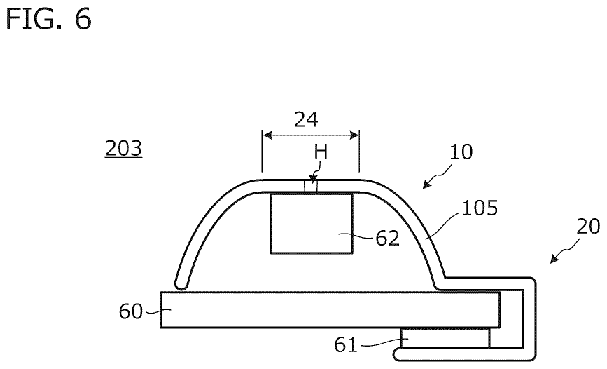

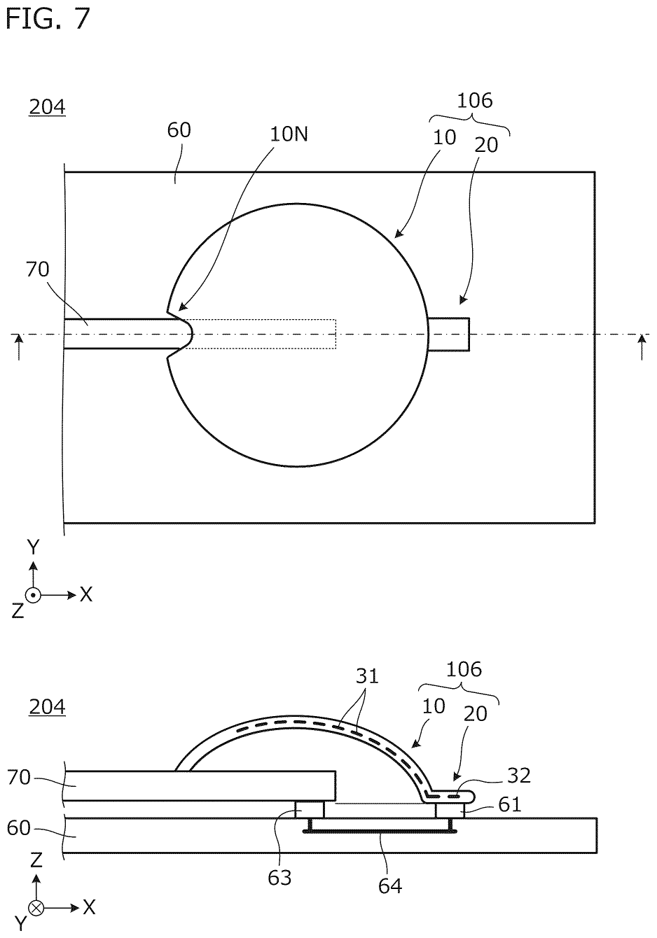

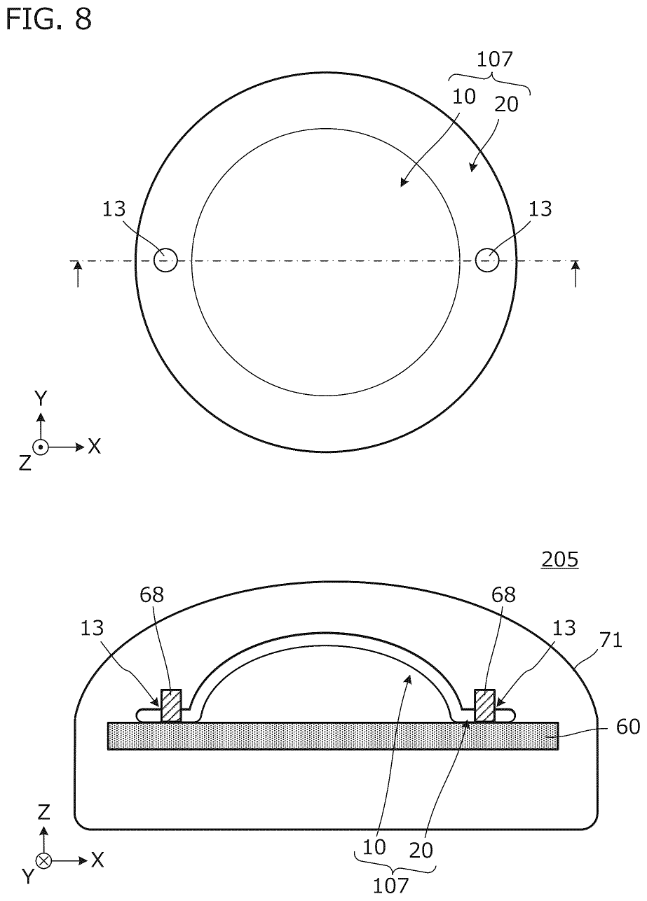

FIG. 6 is a cross-sectional view of another electronic device 203 according to the fourth example embodiment. This electronic device 203 includes a circuit board 60, a multilayer substrate 105, and an electronic component 62 mounted on this multilayer substrate 105 and a connector 61 attached to this multilayer substrate 105. In FIG. 6, prioritizing clarity and visibility of the drawing, illustration of hatching showing a cross-sectional portion is omitted. Although a conductor pattern is formed in the multilayer substrate 105, the conductor pattern is not present at a cross-sectional position in FIG. 6.

As with the example shown in FIG. 4, both the outer shape and inner shape of the multilayer substrate 105 as viewed in the projecting direction of the convex curved surface of the first portion 10 have a circular or substantially circular shape, and a second portion 24 is continuous on an inner side of the inner shape. In addition, the plane shape of the second portion 20 before bending (or curving) is a rectangular or substantially rectangular shape projecting from a portion of positions surrounding the first portion 10.

The electronic component 62 is mounted on the back surface of the second portion 24. The electronic component 62 is, for example, a MEMS microphone. A through hole H is formed in the second portion 24, and the electronic component 62 receives an external sound from the through hole H.

It is to be noted that, although the examples shown in FIG. 5 and FIG. 6 exemplify an electronic device that handles an audio signal, an electronic device that handles an optical signal or a video signal is able to similarly configured.

A fifth example embodiment exemplifies an electronic device including a multilayer substrate at which a notch-shaped portion configuring a non-contact portion or a non-pressing portion to the electronic component is formed in the first portion.

The upper portion of FIG. 7 is a plan view of an electronic device 204, and the lower portion of FIG. 7 is a cross-sectional view of the electronic device 204 taken along a dashed-dotted line shown in the upper portion. This electronic device 204 includes a circuit board 60, a coaxial cable (an electronic component) 70 connected to this circuit board 60 through a connector 63, a multilayer substrate 106, and a connector 61 attached to this multilayer substrate 106. In FIG. 7, prioritizing clarity and visibility of the drawing, illustration of hatching showing a cross-sectional portion is omitted.

A conductor pattern 64 is formed in the circuit board 60. Conductor patterns 31 and 32 as radiation elements, for example, are inside the multilayer substrate 106. One end portion of the conductor pattern 64 is connected to the coaxial cable 70 through the connector 63, and the other end portion is connected to the conductor pattern 32 in the second portion 20 of the multilayer substrate 106 through the connector 61.

A notch-shaped portion 10N configuring a non-abutting portion to the coaxial cable 70 being an electronic component is formed in the first portion 10 of the multilayer substrate 106.

According to the present example embodiment, the multilayer substrate is able to be easily provided together with the electronic component, in a state (a non-contact object or a non-pressing state) of not abutting on the electronic component.

A sixth example embodiment exemplifies a multilayer substrate in which a notch-shaped portion or an opening-shaped portion fixed to a predetermined-shaped member is formed in the second portion, and an electronic device including such a multilayer substrate.

The upper portion of FIG. 8 is a plan view of a multilayer substrate 107. The lower portion of FIG. 8 is a cross-sectional view of an electronic device 205 including the multilayer substrate 107 shown in the upper portion of FIG. 8. This cross-sectional position is at a position taken along a dashed-dotted line shown in the upper portion of FIG. 8.

The multilayer substrate 107 is configured by a first portion 10 and a second portion 20. The first portion 10 has a shape corresponding to a portion of a spherical surface or corresponding to a portion of an approximate spherical surface, and the second portion is a circular or substantially circular ring-shaped flat plate. The second portion is continuous with the periphery of the first portion. An opening 13 is formed in the second portion 20 of the multilayer substrate 107.

The electronic device 205, as shown in the lower portion of FIG. 8, includes a circuit board 60, a pin 68 provided on this circuit board 60, a multilayer substrate 107, and a housing 71 that houses these.

The multilayer substrate 107 is fixed by the opening 13 being inserted into the pin 68 on the circuit board 60.

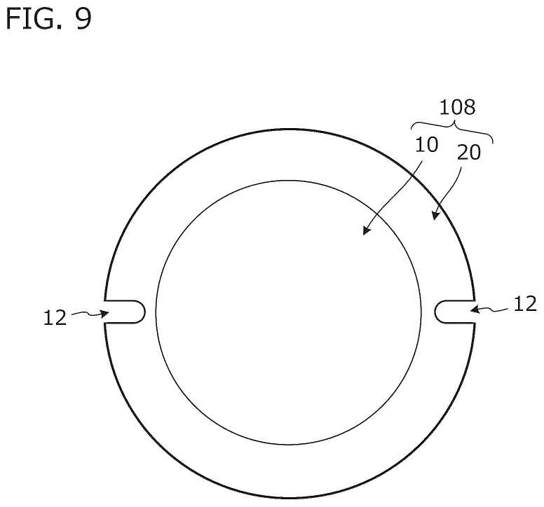

FIG. 9 is a plan view of another multilayer substrate 108 according to the sixth example embodiment. This multilayer substrate 108, as with the example shown in FIG. 8, is configured by the first portion 10 of the shape corresponding to a portion of a spherical surface or corresponding to a portion of an approximate spherical surface, and the second portion 20 being a circular or substantially circular ring-shaped flat plate. The multilayer substrate 108, being different from the multilayer substrate 107 shown in FIG. 8, includes a notch portion 12 formed in the second portion 20.

The multilayer substrate 108 is able to be fixed by fixing the notch portion to a predetermined-shaped member such as a portion of the circuit board.

It is to be noted that, although the examples shown in FIG. 8 and FIG. 9 show an example in which the second portion 20 has a circular or substantially circular ring shape, the ring shape is not limited to a circle. For example, the outer shape of the second portion 20 may be a polygon such as a quadrilateral shape, or a polygon with rounded corner portions.

A seventh example embodiment exemplifies an electronic device including a multilayer substrate and an electronic component installed on the multilayer substrate.

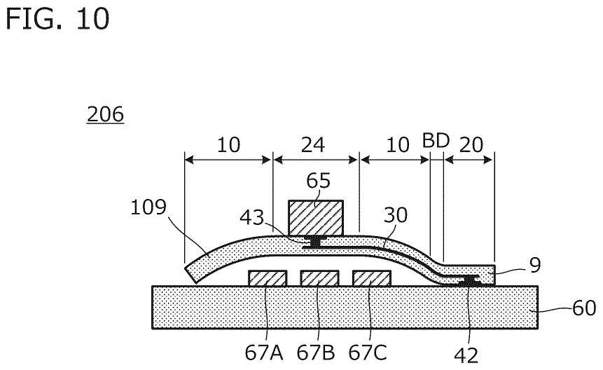

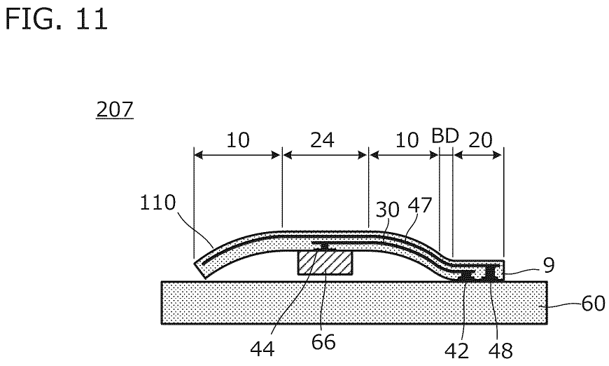

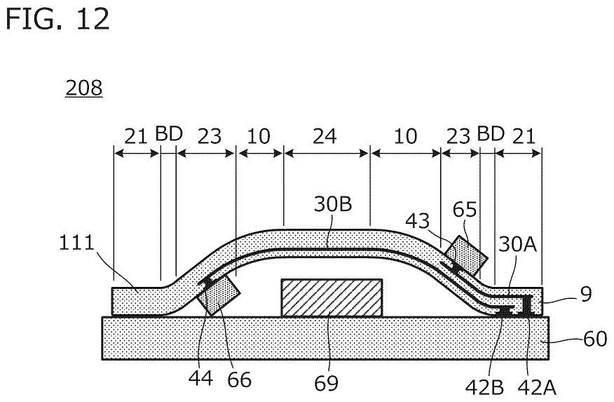

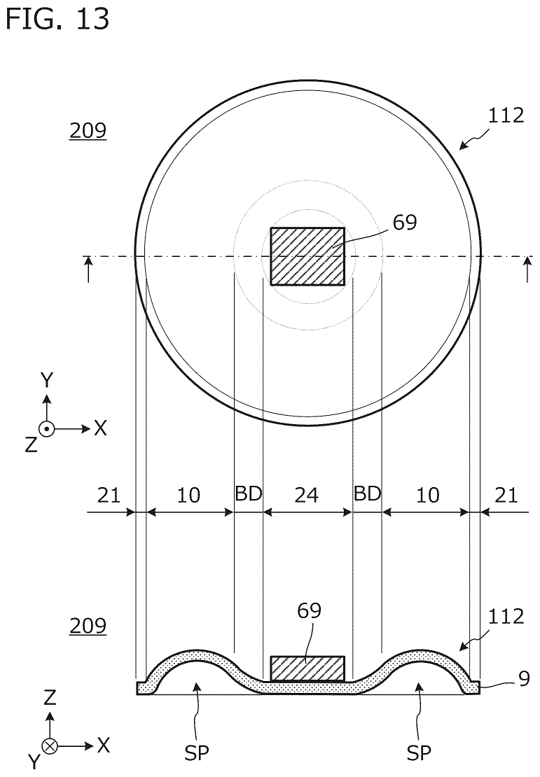

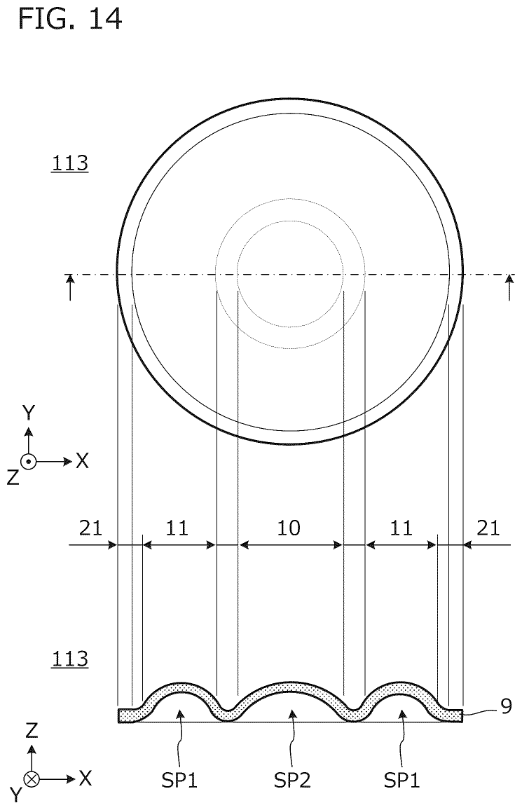

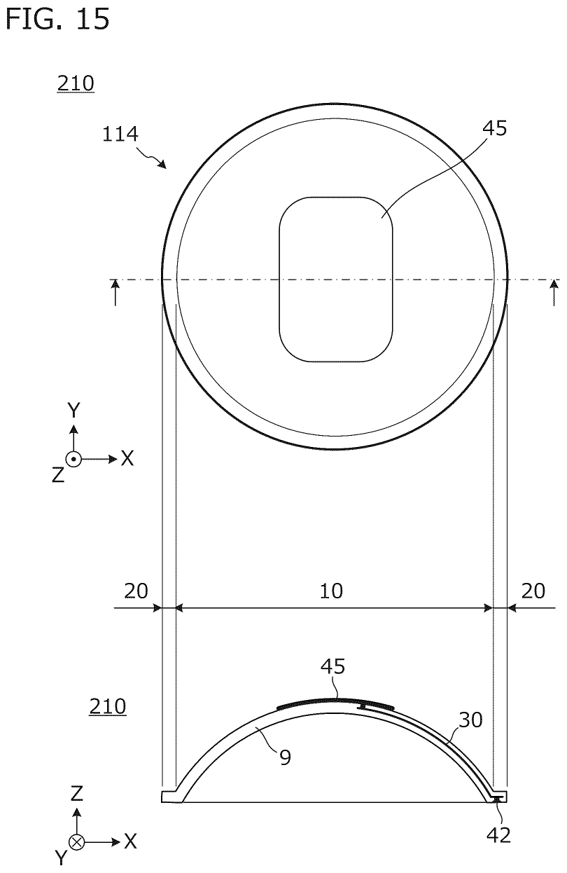

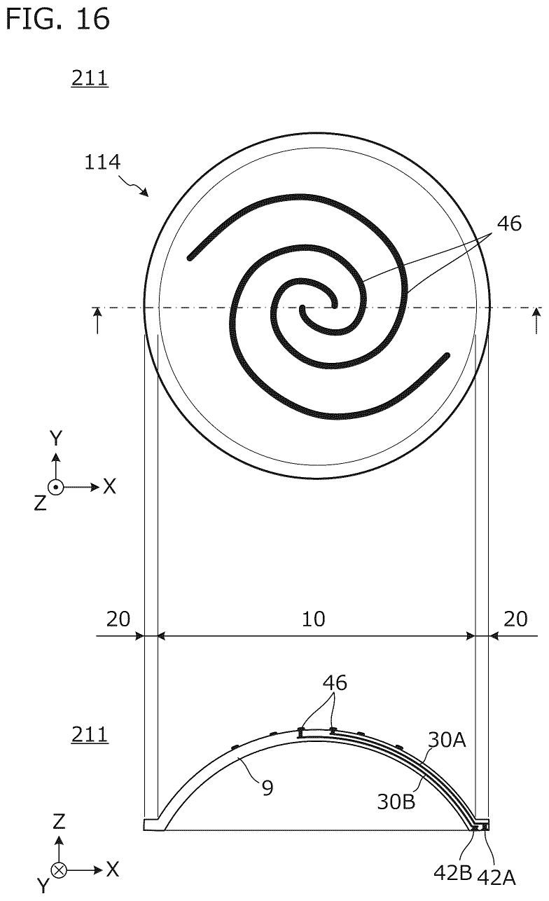

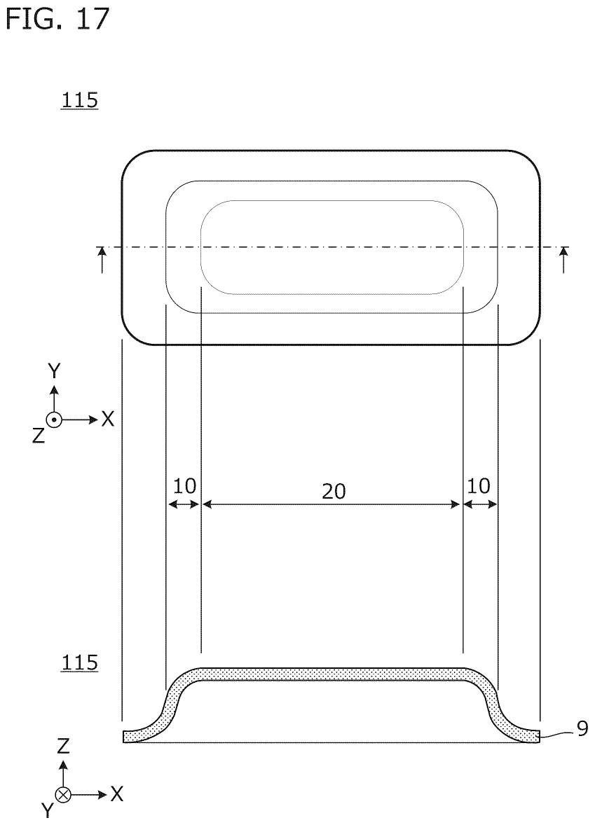

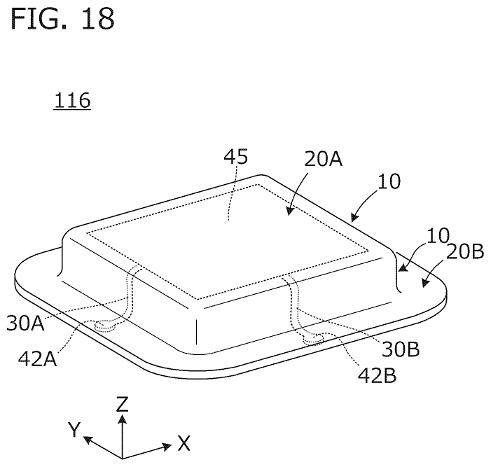

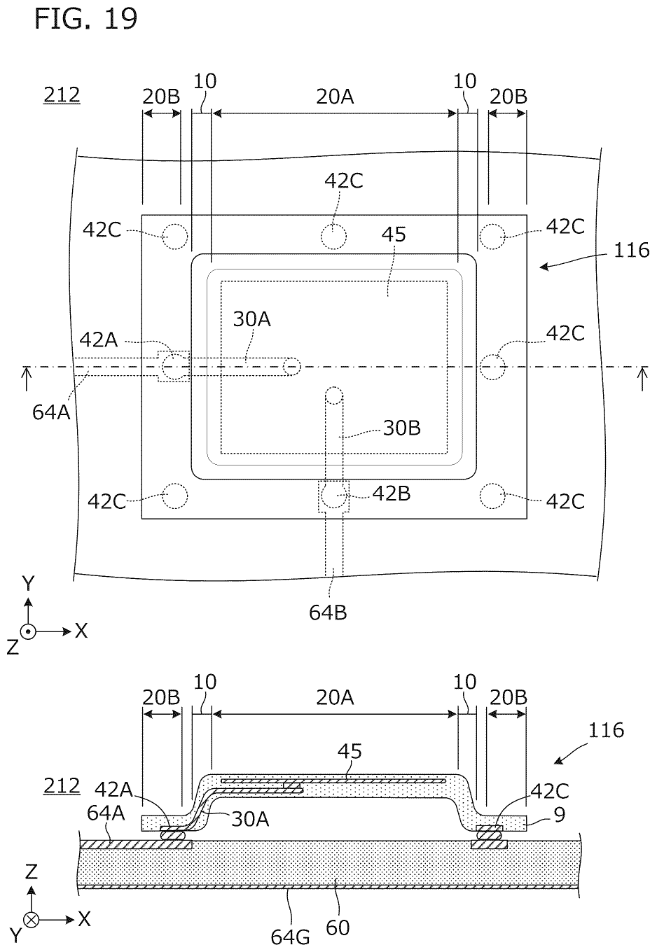

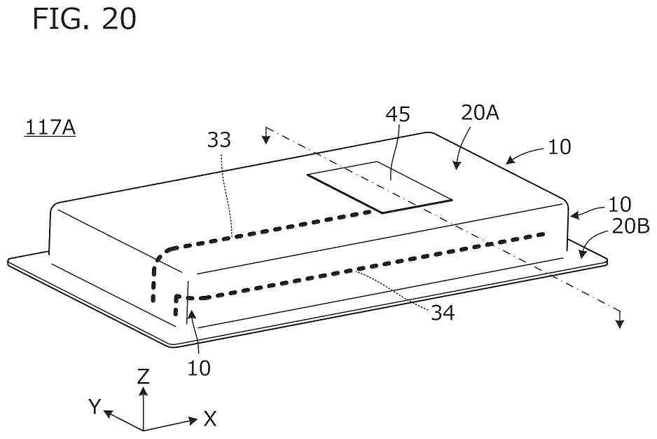

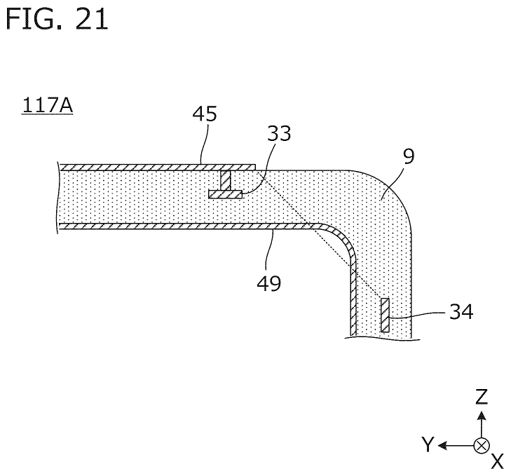

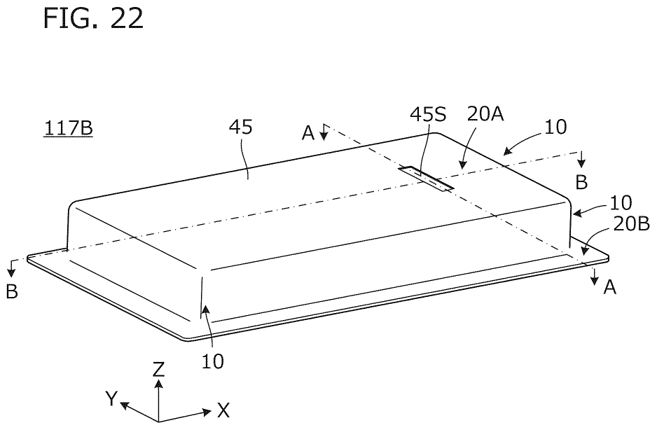

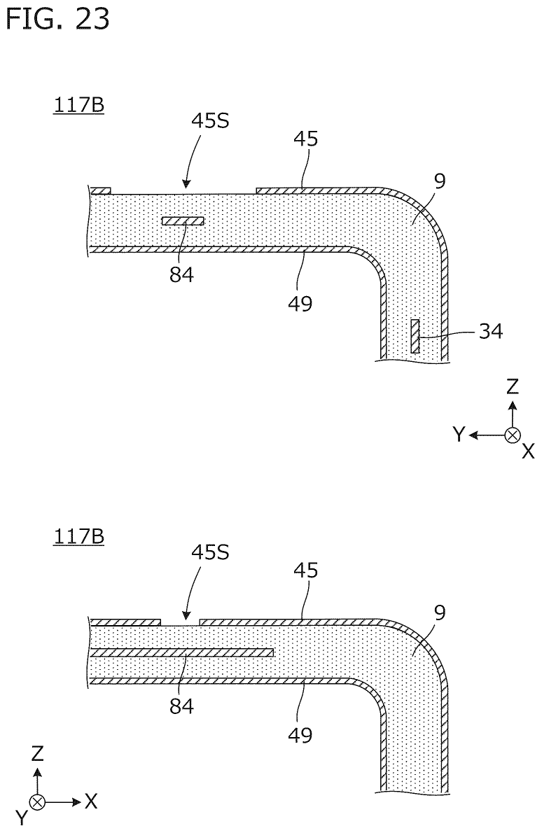

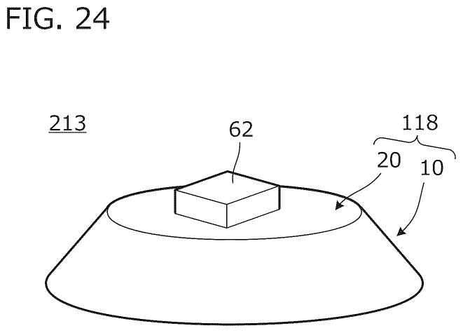

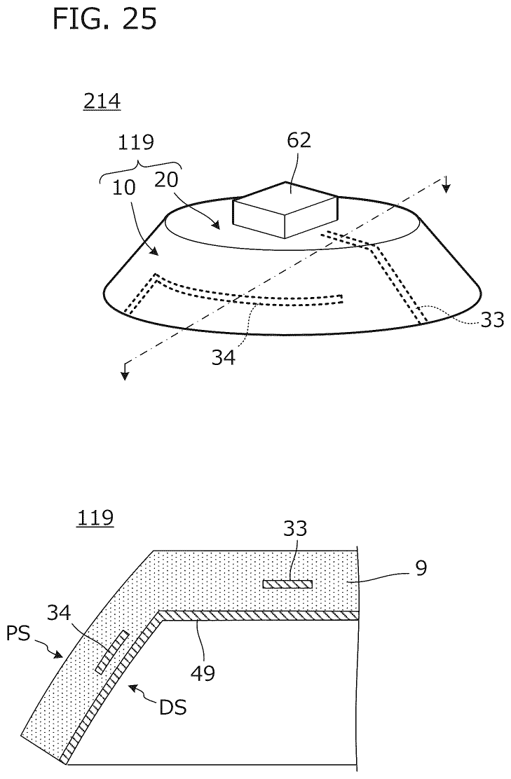

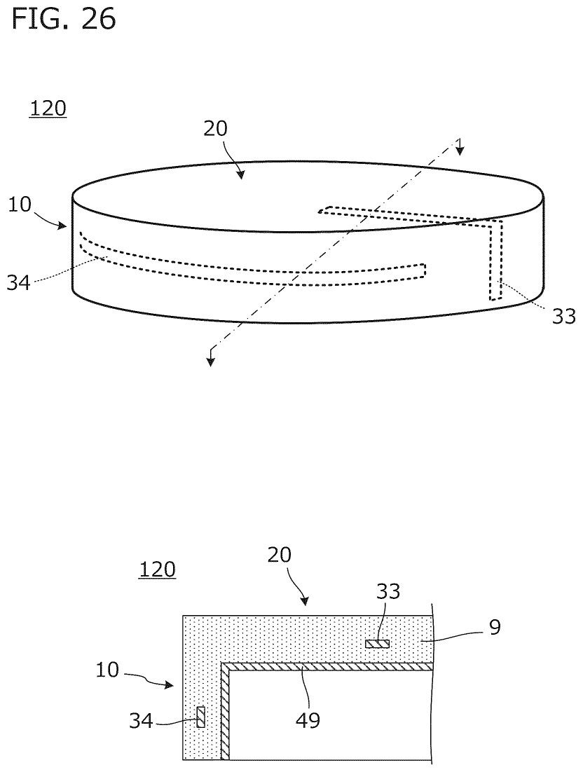

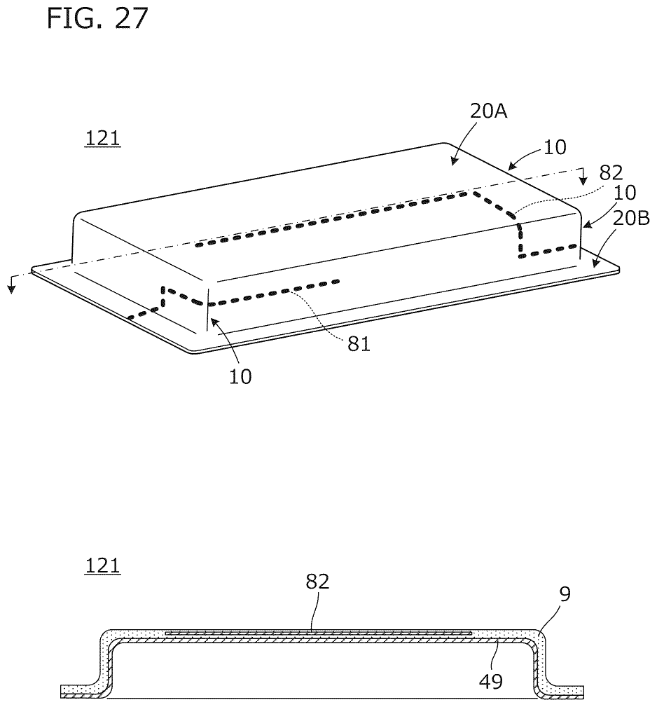

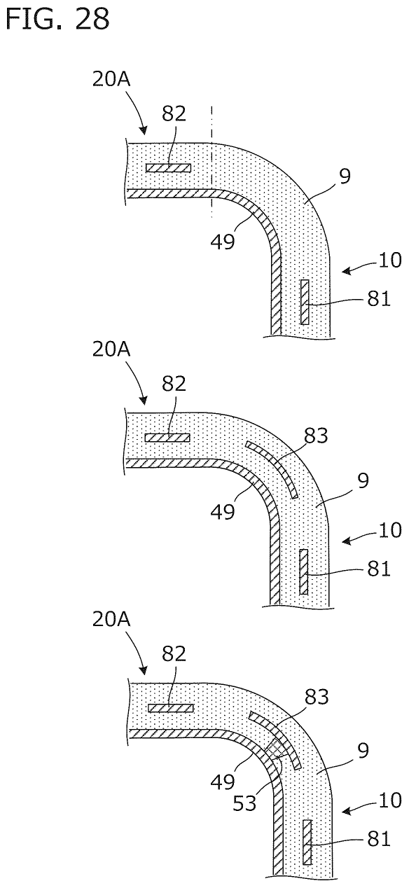

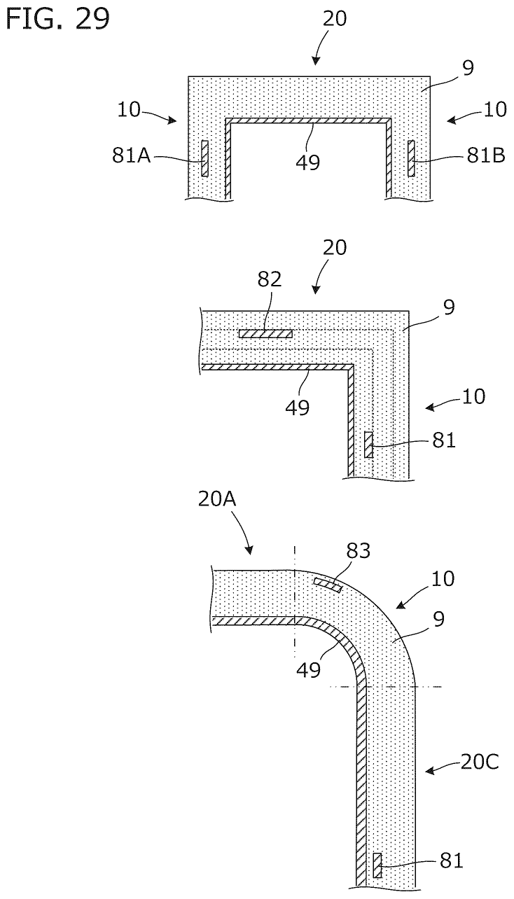

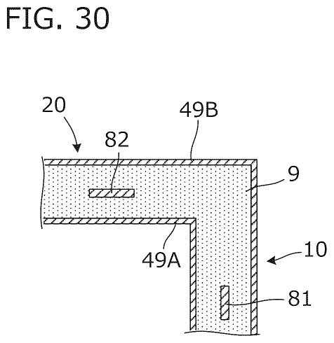

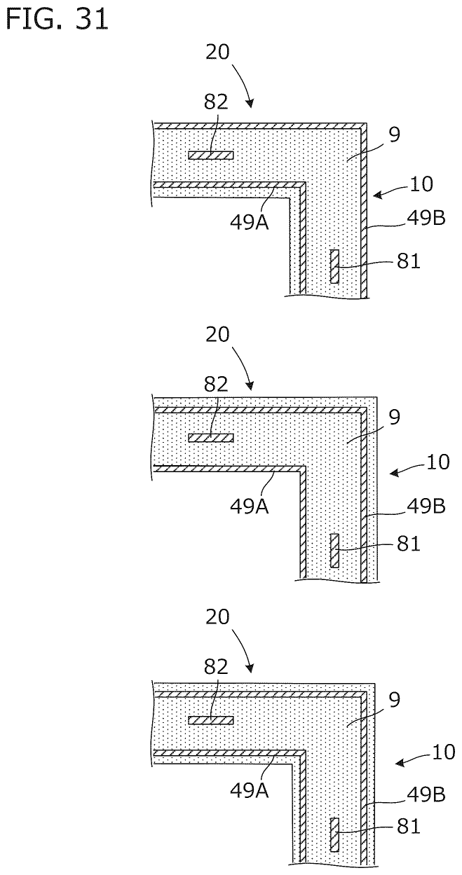

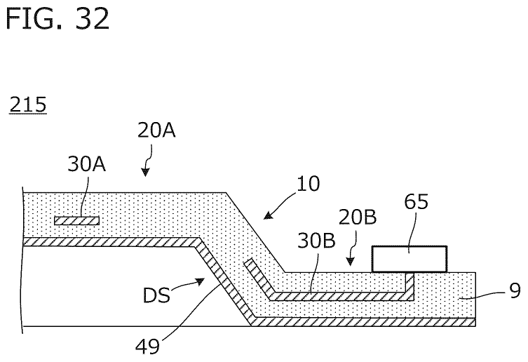

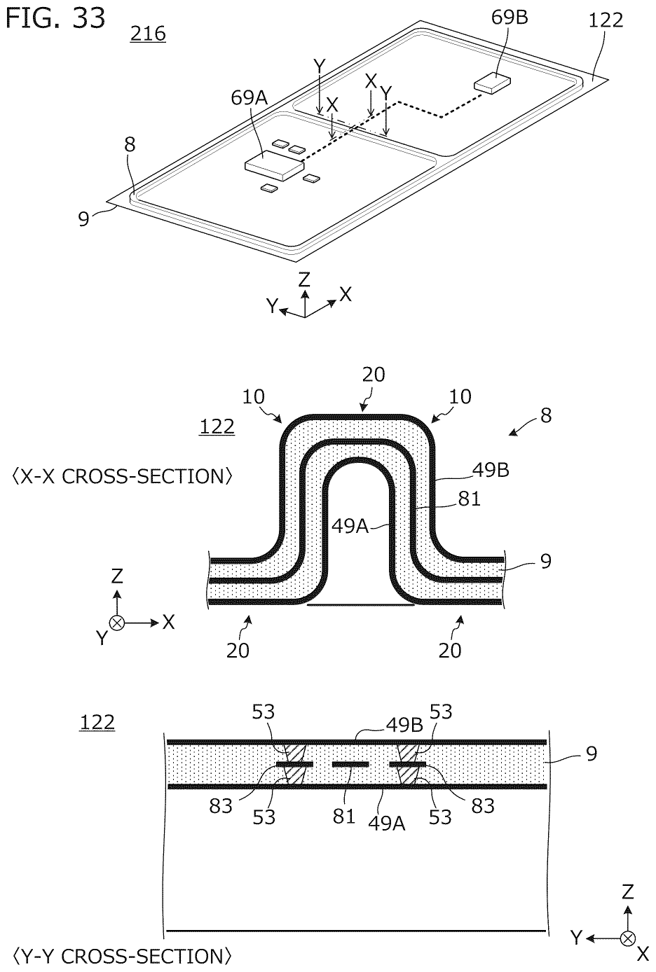

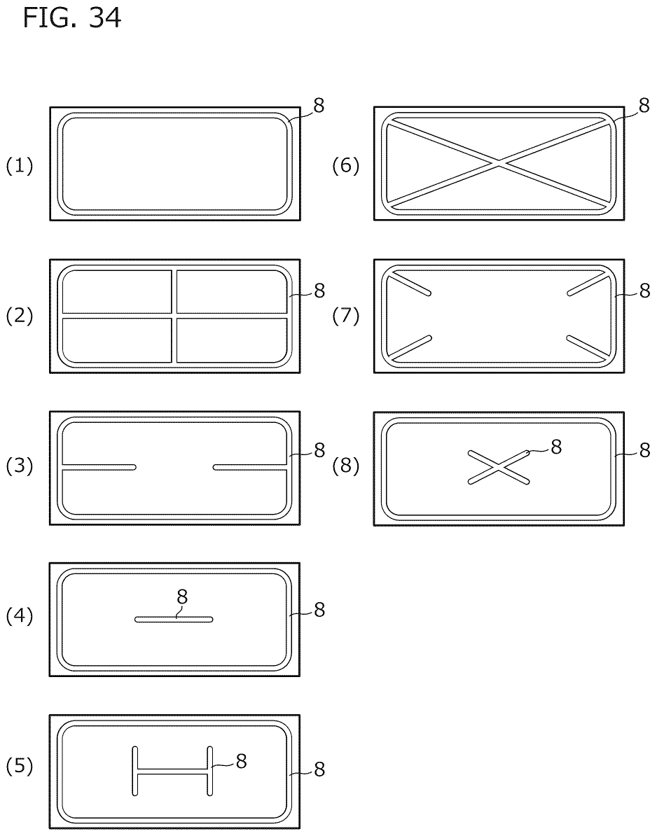

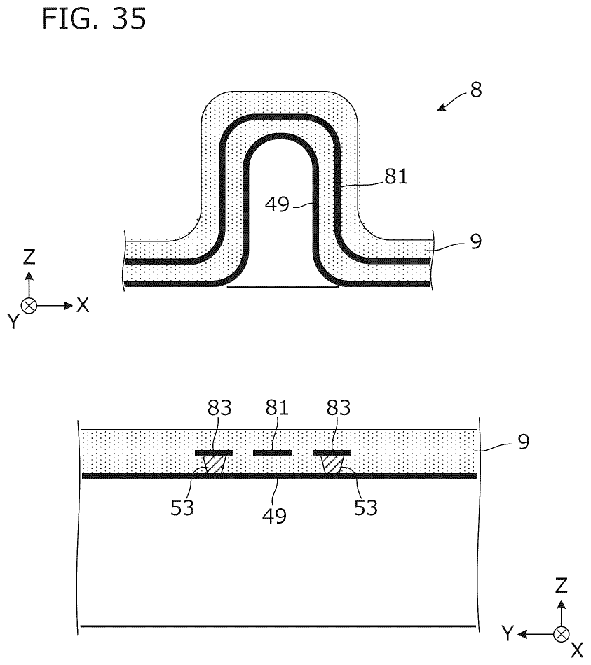

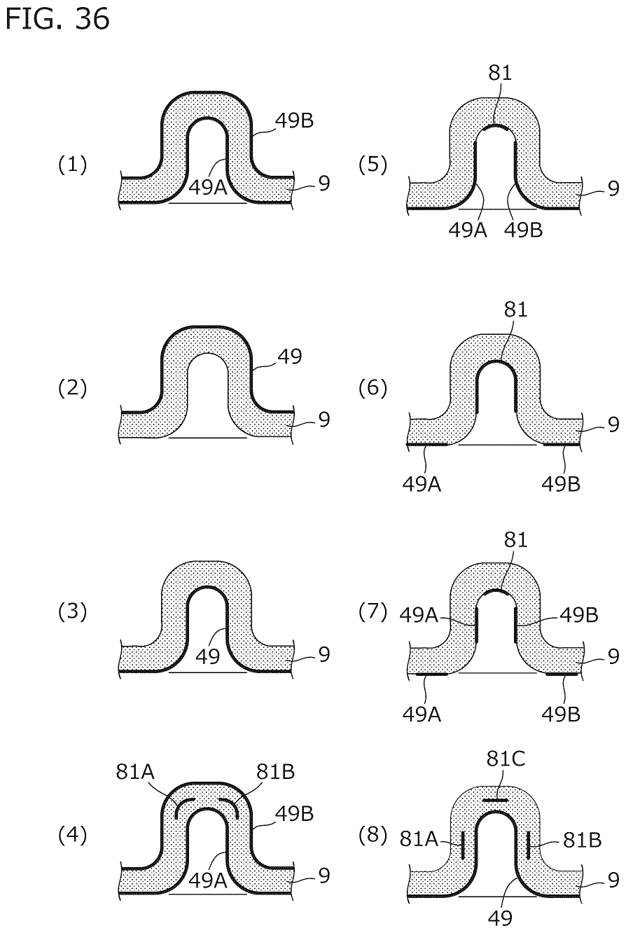

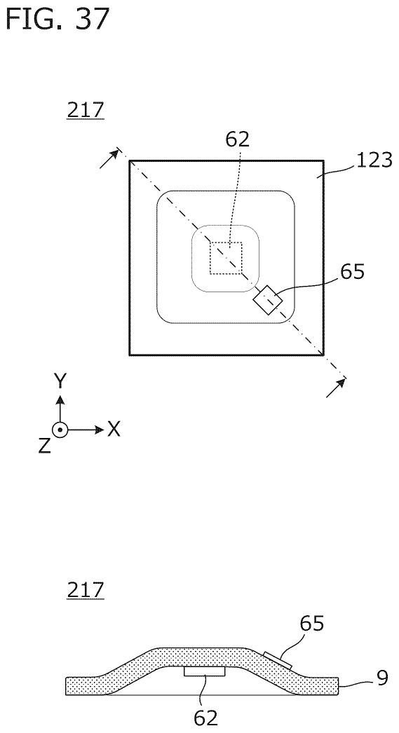

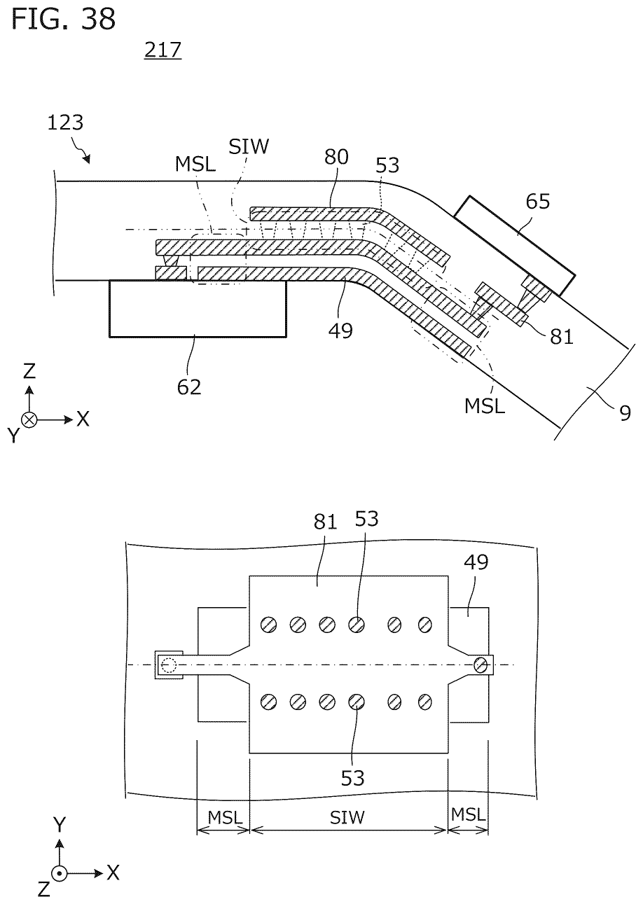

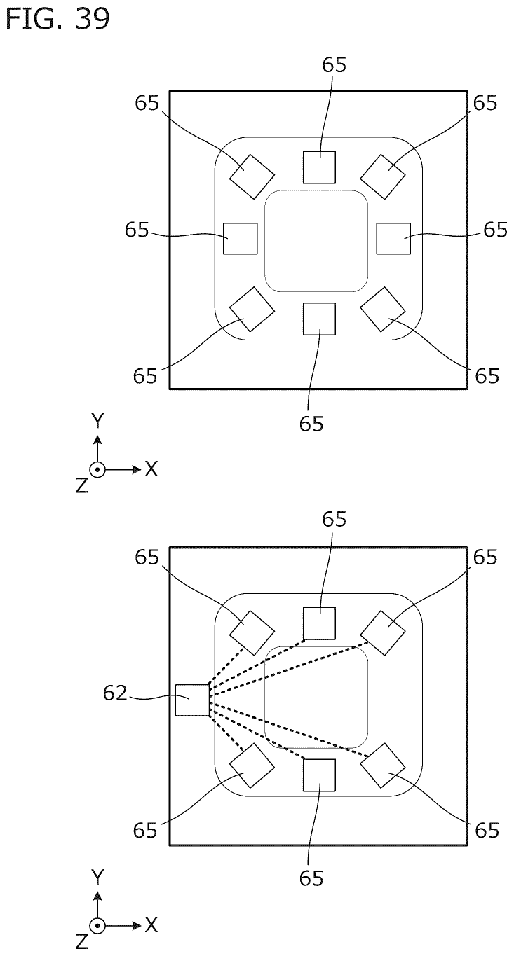

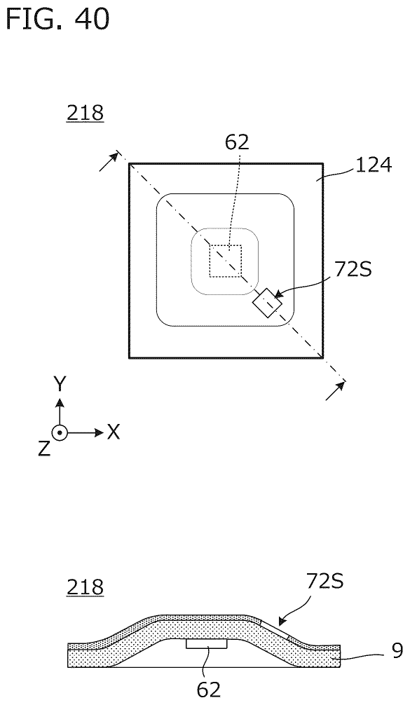

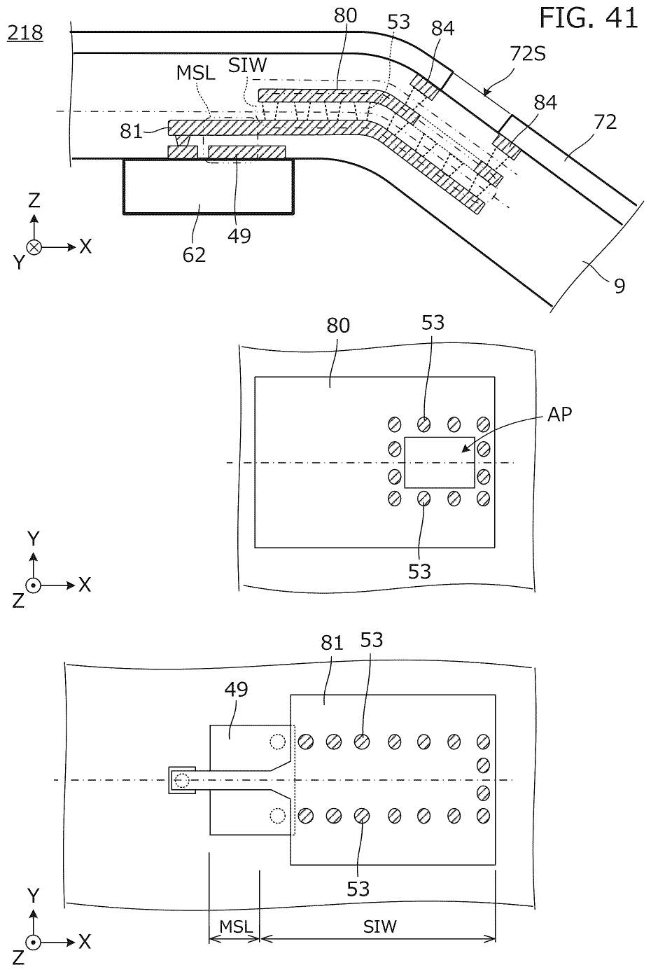

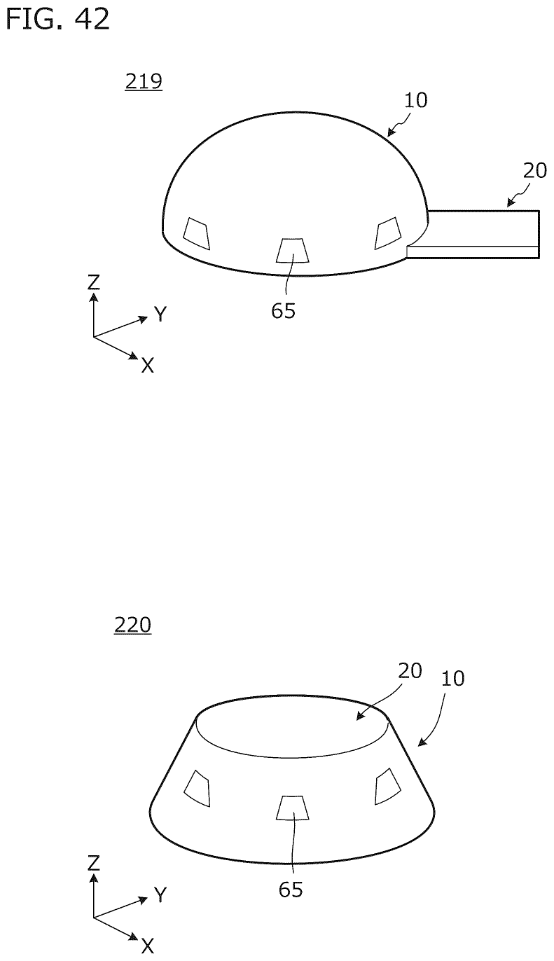

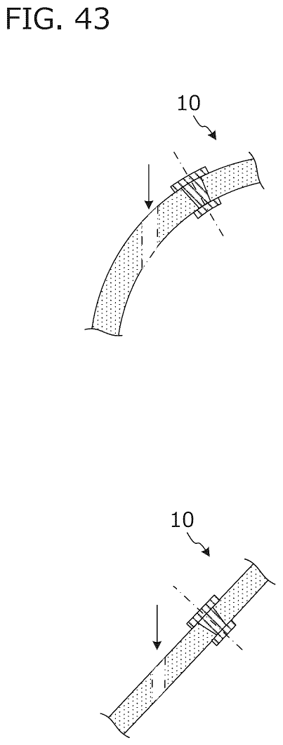

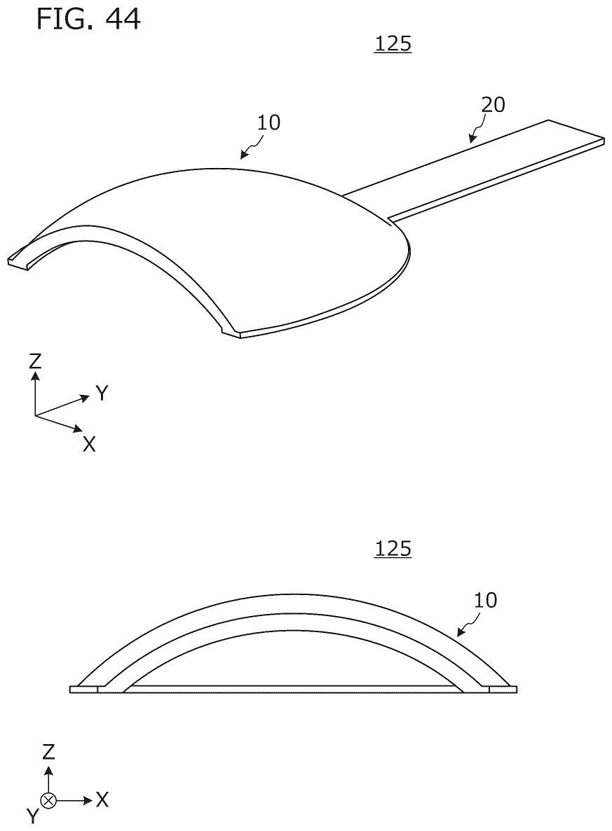

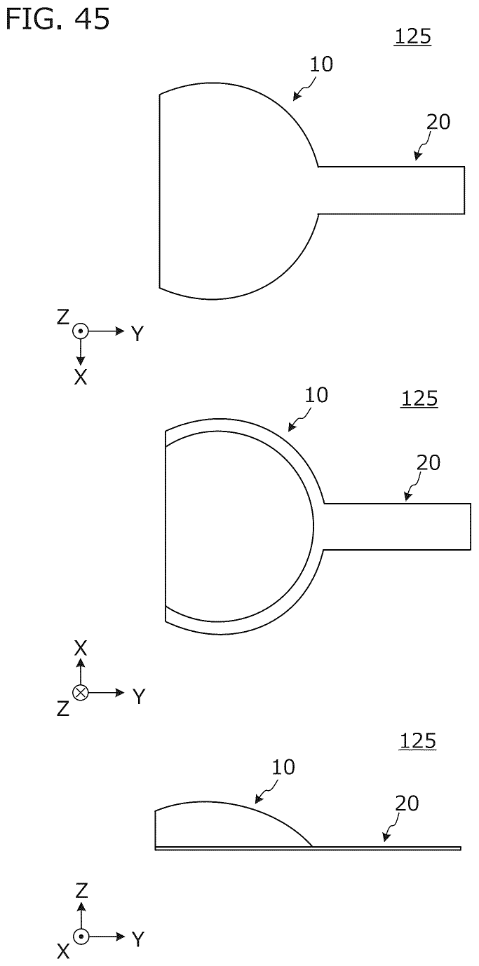

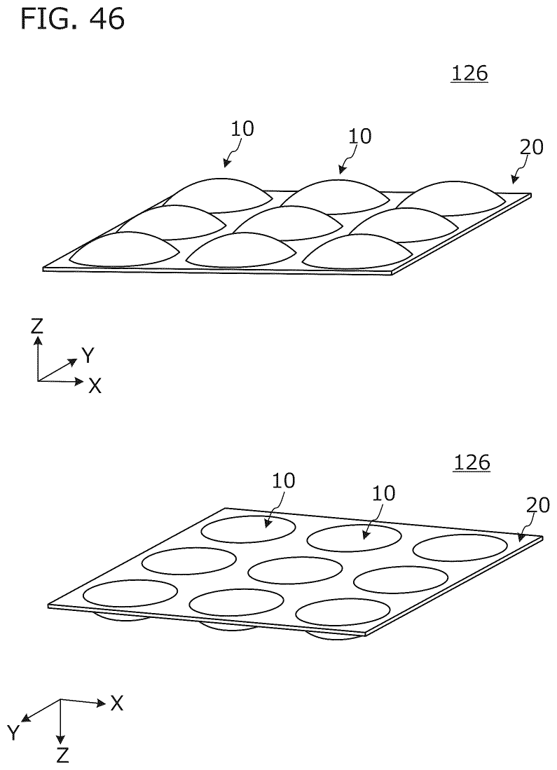

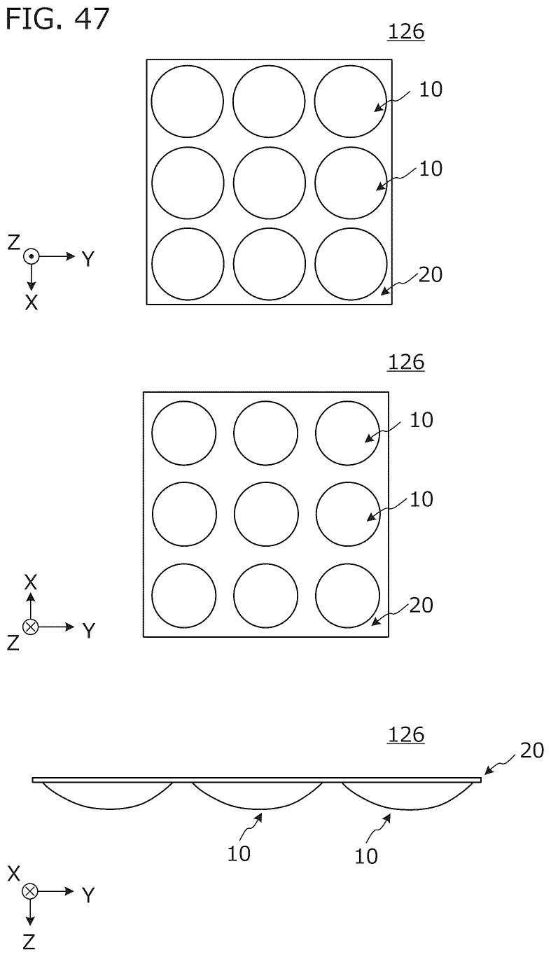

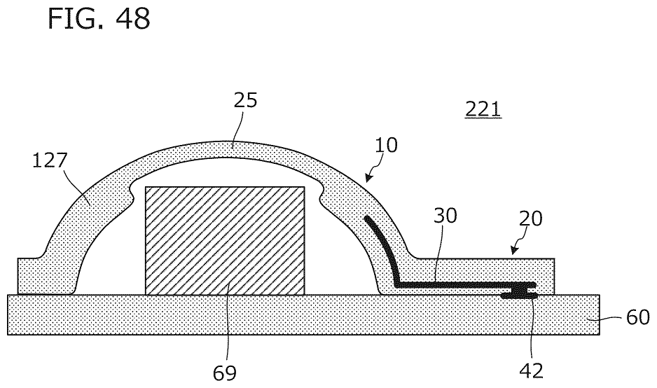

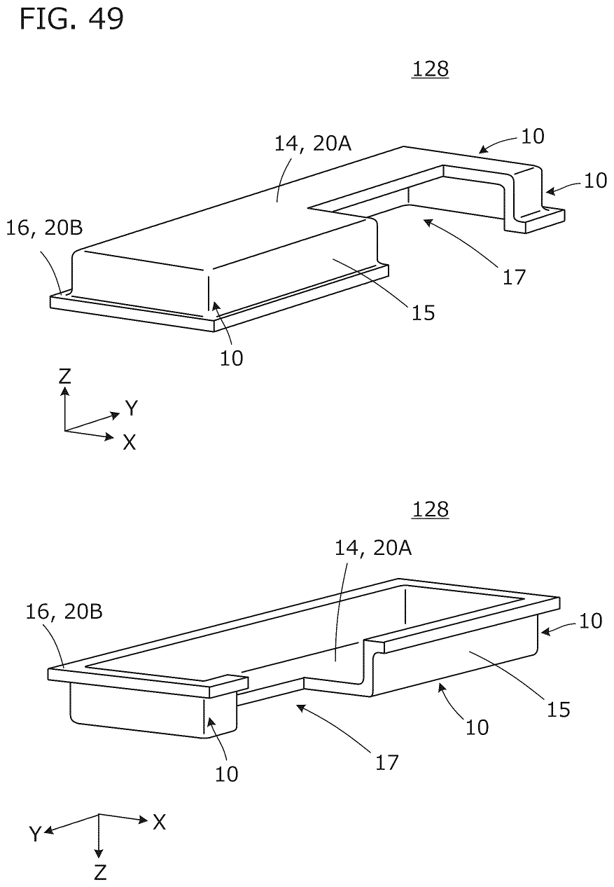

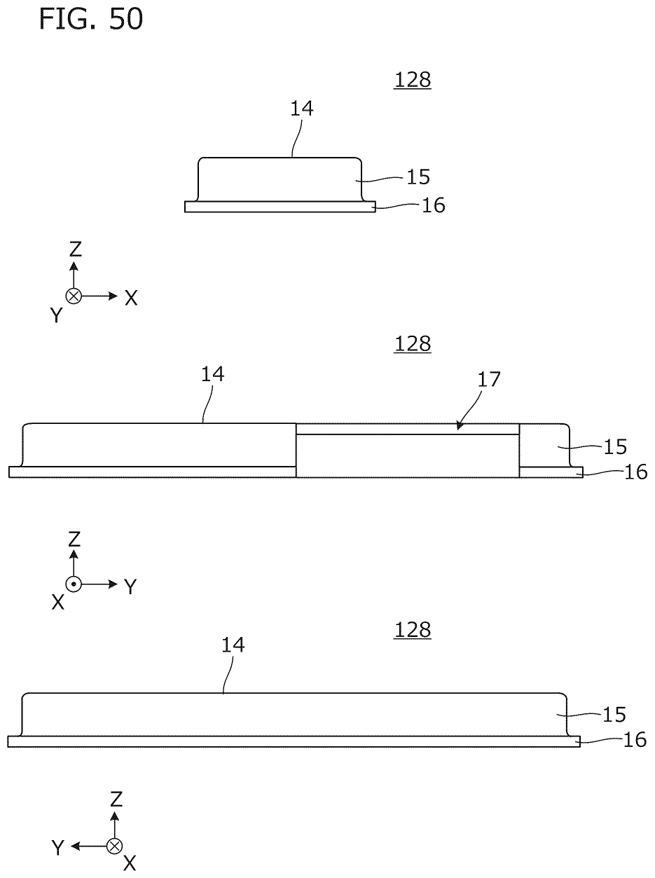

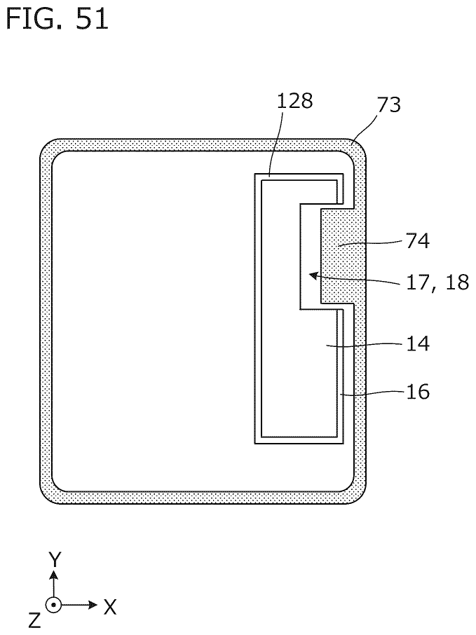

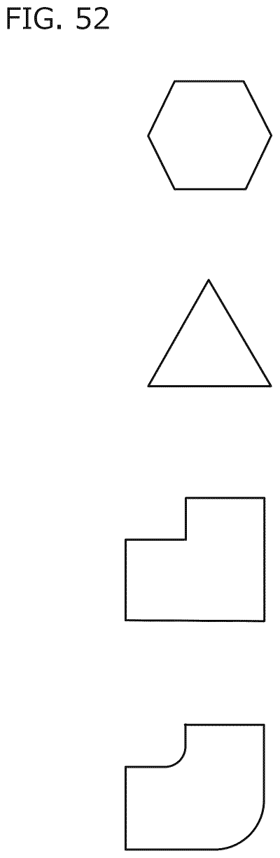

FIG. 10, FIG. 11, and FIG. 12 are cross-sectional views of each electronic device according to the seventh example embodiment.

FIG. 10 is a cross-sectional view of an electronic device 206 configured by installing a multilayer substrate 109 on which an electronic component 65 is mounted, on a circuit board 60. The multilayer substrate 109 includes a first portion 10 and second portions 20 and 24. The plane shape of the first portion 10 as viewed in the projecting direction of the convex curved surface is circular or substantially circular ring shaped. In addition, the shape of the second portion 24 as viewed in the projecting direction of the convex curved surface is circular or substantially circular. In addition, the outer shape of the second portion 20 as viewed in the projecting direction of the convex curved surface is rectangular or substantially rectangular parallelepiped shaped.

It is to be noted that the shape of the second portion 24 as viewed in the projecting direction of the convex curved surface is not limited to be a circle. For example, the shape may be a polygon such as a quadrilateral shape, or a polygon with rounded corner portions. In addition, the first portion 10 as viewed in the projecting direction of the convex curved surface is not limited to a circular or substantially circular ring shape. For example, the shape may be a ring shape of a polygon such as a quadrilateral shape, or a ring shape of a polygon with rounded corner portions.

In the example shown in FIG. 10, at the boundary BD between the second portion 20 and the first portion 10, the front surface of the multilayer substrate 109 is a concave curved surface and the back surface is a convex curved surface facing the concave curved surface.

A conductor pattern 30 is formed in an inner layer of the multilayer substrate 109. A terminal electrode 42 is located at an end portion of the multilayer substrate 109. In addition, a terminal electrode 43 for mounting the electronic component 65 is located at a predetermined position of the front surface of the multilayer substrate 109. The conductor pattern 30 functions as a wiring pattern between the terminal electrode 42 and the terminal electrode 43.

Electronic components 67A, 67B, and 67C are mounted on the front surface of the circuit board 60. The terminal electrode 42 of the multilayer substrate 109 is connected to a terminal electrode of this circuit board 60, which makes it possible to install the multilayer substrate 109 on which the electronic component 65 has been already mounted, on the circuit board 60. In this manner, in a state in which the multilayer substrate 109 is mounted on the circuit board 60, the electronic components 67A, 67B, and 67C are present in a space between the first portion 10 and second portion 24 of the multilayer substrate 109, and the circuit board 60. Therefore, the electronic components 67A, 67B, and 67C are able to be protected by the multilayer substrate 109 from an external impact such as collision with an object. In addition, the electronic components 67A, 67B, and 67C are able to be arranged in a concave portion of the multilayer substrate 109, which makes it possible to effectively use the space of the concave portion of the multilayer substrate 109 and to miniaturize the whole.

FIG. 11 is a cross-sectional view of an electronic device 207 configured by installing a multilayer substrate 110 on which an electronic component 66 is mounted, on the circuit board 60. The multilayer substrate 110 includes a first portion 10, second portions 20 and 24, and a boundary BD. The plane shape of the multilayer substrate 110 is the same as the plane shape of the multilayer substrate 109.

Conductor patterns 30 and 47 are formed in an inner layer of the multilayer substrate 110. Terminal electrodes 42 and 48 are located at an end portion of the multilayer substrate 110. In addition, a terminal electrode 44 for mounting the electronic component 66 is located at a predetermined position of the back surface of the multilayer substrate 110. The conductor pattern 30 functions as a wiring pattern between the terminal electrode 42 and the terminal electrode 44. The conductor pattern 47 forms a conductor layer expanding in a plane direction of the multilayer substrate 110. This conductor pattern 47 is connected to the ground of the circuit board 60 through the terminal electrode 48. Therefore, the entire lower portion of the multilayer substrate 110 including the electronic component 66 is electromagnetically shielded. It is to be noted that, depending on the purpose of the electromagnetic shielding of the electronic component 66 or the lower portion of the multilayer substrate 110, the conductor pattern 47 does not need to be connected to the ground. In addition, the conductor pattern 47 may be formed on the upper surface of the multilayer substrate 110.

As shown in FIG. 11, the terminal electrode 42 of the multilayer substrate 110 is connected to the terminal electrode of the circuit board 60, which makes it possible to install the multilayer substrate 110 on which the electronic component 66 has been already mounted, on the circuit board 60. In this manner, in a state in which the multilayer substrate 110 is installed on the circuit board 60, the electronic component 66 is present in a space between the first portion 10 and second portion 24 of the multilayer substrate 110, and the circuit board 60. Therefore, the electronic component 66 is able to be protected by the multilayer substrate 110 from an external impact such as collision with an object.

FIG. 12 is a cross-sectional view of an electronic device 208 configured by installing a multilayer substrate 111 on which electronic components 65 and 66 are mounted, on the circuit board 60. The multilayer substrate 111 includes a first portion 10, second portions 21, 23 and 24, and a boundary BD. All plane shapes of the first portion 10 as viewed in the projecting direction of the convex curved surface is circular or substantially circular ring shaped. In addition, the shape of the second portion 24 as viewed in the projecting direction of the convex curved surface is circular or substantially circular. In addition, the plane shape of the second portion 21 as viewed in the projecting direction of the convex curved surface is circular or substantially circular ring shaped. Further, the plane shape of the boundary BD between the second portion 21 and the second portion 23 is also circular or substantially circular ring shaped.

Conductor patterns 30A and 30B are formed in an inner layer of the multilayer substrate 111. Terminal electrodes 42A and 42B are located at an end portion of the multilayer substrate 111. In addition, the terminal electrode 43 for mounting the electronic component 65 is located at a predetermined position of the front surface of the multilayer substrate 111, and the terminal electrode 44 for mounting the electronic component 66 is located at a predetermined position of the back surface of the multilayer substrate 111. The conductor pattern 30A functions as a wiring pattern between the terminal electrode 42A and the terminal electrode 43. In addition, the conductor pattern 30B functions as a wiring pattern between the terminal electrode 42B and the terminal electrode 44.

An electronic component may be mounted on both front and back surfaces of a multilayer substrate as in the example shown in FIG. 12.

An eighth example embodiment exemplifies a multilayer substrate including a plurality of spaces configured by a curved surface including a first portion, in a cross-section along a stacking direction, and an electronic device including such a multilayer substrate.

The upper portion of FIG. 13 is a plan view of an electronic device 209 according to the eighth example embodiment, and the lower portion of FIG. 13 is a cross-sectional view of the electronic device 209 taken along a dashed-dotted line in the upper portion of FIG. 13. The electronic device 209 is configured by a multilayer substrate 112, and an electronic component 69 mounted on the multilayer substrate.

The multilayer substrate 112 includes a first portion 10 and second portions 21 and 24. A boundary BD is formed between the first portion 10 and the second portion 24. The electronic component 69 is mounted on the second portion 24 of this multilayer substrate 112.

This multilayer substrate 112 includes a horizontal-cut doughnut-shaped space SP configured by a curved surface including the first portion 10. In the cross-section, as shown in FIG. 13, two spaces SP and SP are present. An electronic component or a member of a device, for example, is also able to be arranged in these spaces.

The upper portion of FIG. 14 is a plan view of another multilayer substrate 113 according to the eighth example embodiment, and the lower portion of FIG. 14 is a cross-sectional view of the multilayer substrate 113 taken along a dashed-dotted line in the upper portion of FIG. 14.

The multilayer substrate 113 includes first portions 10 and 11, and a second portions 21. A boundary is formed between the first portion 10 and the first portion 11. In addition, a boundary is formed between the first portion 11 and the second portion 21.

The multilayer substrate 113 includes a horizontal-cut doughnut-shaped space SP1 configured by a curved surface including the first portion 11. In addition, this multilayer substrate 113 includes a horizontal-cut circular or substantially circular-shaped space SP2 configured by a curved surface including the first portion 10. In the cross-section, as shown in the cross-sectional view of FIG. 14, two spaces SP1 and SP2 are present. In addition, an electronic component or a member of a device, for example, is also able to be arranged in these spaces.

Generally, stress is applied to each portion of a multilayer substrate by an external force applied to the multilayer substrate from an outer surface of the multilayer substrate mounted on something, or from a mounting surface of the multilayer substrate. According to the present example embodiment, in a cross-section of the multilayer substrate 112 and 113, a plurality of spaces (SP), and (SP1, SP2) are present, which significantly reduces an amount of deformation to the stress applied to the multilayer substrate 112 and 113. In other words, the rigidity of the multilayer substrate 112 and 113 is able to be increased.

A ninth example embodiment exemplifies an electronic device configured by forming a different conductor pattern from the examples described above, on a multilayer substrate.

The upper portion of FIG. 15 is a plan view of an electronic device 210 according to the ninth example embodiment. The lower portion of FIG. 15 is a cross-sectional view taken along a dashed-dotted line in the upper portion of FIG. 15.

This electronic device 210 includes a multilayer substrate 114, and a conductor pattern 45 formed on a surface of the multilayer substrate.

The multilayer substrate 114 is configured by a first portion 10 and a second portion 20. The outer shape of the plane shape of the first portion 10 is circular or substantially circular. The plane shape of the second portion 20 is circular or substantially circular ring shaped. A conductor pattern 30 is formed in an inner layer of the multilayer substrate 114. A terminal electrode 42 is located at an end portion of the multilayer substrate 114.

A conductor pattern 45 of a patch antenna is located at a predetermined position of the front surface of the multilayer substrate 114. One end of the conductor pattern 30 is connected to the terminal electrode 42 through a connection conductor that is present in a stacking direction of base material layers 9. In addition, the other end of the conductor pattern 30 is connected to a predetermined position of the conductor pattern 45 through the connection conductor that is present in the stacking direction of the base material layers 9.

In this manner, the patch antenna may be configured at the first portion 10 of the multilayer substrate 114.

The upper portion of FIG. 16 is a plan view of another electronic device 211 according to the ninth example embodiment. The lower portion of FIG. 16 is a cross-sectional view taken along a dashed-dotted line in the upper portion of FIG. 16.

This electronic device 211 includes a multilayer substrate 114, and a conductor pattern 46 formed on a surface of the multilayer substrate. The multilayer substrate 114 is the same as the multilayer substrate 114 shown in FIG. 15.

Conductor patterns 30A and 30B are formed in an inner layer of the multilayer substrate 114. Terminal electrodes 42A and 42B are located at an end portion of the multilayer substrate 114.

A conductor pattern 46 of a double-spiral antenna is located at a predetermined position of the front surface of the first portion 10 of the multilayer substrate 114. One end of the conductor patterns 30A and 30B is connected to each of the terminal electrodes 42A and 42B through a connection conductor that is present in the stacking direction of the base material layers 9. In addition, the other end of the conductor patterns 30A and 30B is connected to an inner peripheral end of the conductor pattern 46 through the connection conductor that is present in the stacking direction of the base material layers 9.

In this manner, the double-spiral antenna may be configured at the first portion 10 of the multilayer substrate 114.

A tenth example embodiment exemplifies a multilayer substrate having a shape (that is, including a plane in a projected surface (a projecting portion)) in which the second portion projects by the first portion.

The upper portion of FIG. 17 is a plan view of a multilayer substrate 115 according to the tenth example embodiment. The lower portion of FIG. 17 is a cross-sectional view at a position shown by a dashed-dotted line in the upper portion of FIG. 17.

This multilayer substrate 115 includes a first portion 10 and a second portion 20. The plane shape of the first portion 10 is a rectangular ring shape with rounded corner portions. The plane shape of the second portion 20 is a rectangular or substantially rectangular shape with rounded corner portions. The outer shape as viewed in the projecting direction of the convex curved surface of the first portion 10 in the examples described above, although being circular or substantially circular, may be a polygonal shape as in the present example embodiment. In addition, the outer shape may be a polygonal shape with rounded corner portions.

In the example shown in FIG. 17, the entire front surface of the first portion 10 is not necessarily a surface that curves around an axis in the projecting direction (the Z direction), and the convex curved surface of the front surface of the first portion 10 is present at four locations around the axis of the projecting direction (the Z direction).

An eleventh example embodiment exemplifies a multilayer substrate that is different in the shape of a first portion and a second portion from the multilayer substrate described above, and an electronic device including such a multilayer substrate.

FIG. 18 is a perspective view of a multilayer substrate 116 according to the eleventh example embodiment. The upper portion of FIG. 19 is a plan view of an electronic device 212 including the multilayer substrate 116, and the lower portion of FIG. 19 is a cross-sectional view taken along a dashed-dotted line shown in the upper portion of FIG. 19.

This multilayer substrate 116 includes a first portion 10 and second portions 20A and 20B. As shown in FIG. 18 and FIG. 19, the plane shape of the second portion 20A is a rectangular or substantially rectangular shape with rounded corner portions, and the plane shape of the second portion 20B is a rectangular ring shape with rounded corner portions at an inner periphery.

The front surface of the first portion 10 is a convex curved surface, the back surface of the first portion 10 is a concave curved surface that faces the convex curved surface and gives the thickness to the multilayer substrate 116, and a thickness between the front and back surfaces of the second portions 20A and 20B that face each other is constant or approximately constant.

A conductor pattern 45 as a radiation element (a patch antenna) is formed in an inner layer of the base material layers 9 of the second portion 20A. In addition, conductor patterns 30A and 30B as wiring conductor patterns are formed in the inner layer of the base material layers 9 of the second portions 20A and 20B and the first portion 10. One end of these conductor patterns 30A and 30B is connected to the conductor pattern 45 through an interlayer connection conductor.

Terminal electrodes 42A, 42B, and 42C are located at the second portion 20B, and these terminal electrodes 42A, 42B, and 42C are exposed on the lower surface of the second portion 20B. The other end of the conductor patterns 30A and 30B is continuous with the terminal electrodes 42A and 42B. These terminal electrodes 42A, 42B, and 42C function as mounting electrodes to the circuit board 60. Conductor patterns 64A and 64B as signal lines and a conductor pattern 64G as a ground conductor layer are located at the circuit board 60.

In this example embodiment, two locations of the conductor pattern 45 as the radiation element are used as feeding points, which makes it possible to use the conductor pattern 45 as the radiation element having two polarization planes.

As shown in this example embodiment, the multilayer substrate 116 may include two second portions 20A and 20B, and the second portion 20B to be mounted on the circuit board 60 may have the terminal electrodes 42A, 42B, and 42C.

It is to be noted that the outer shape of the multilayer substrate 116, even when being a circular or substantially circular shape in addition to being a quadrangular shape, is able to be configured in a similar manner. The conductor pattern 45 as the radiation element may also have a circular or substantially circular shape or a polygonal shape in addition to a quadrangular shape. Furthermore, the second portion 20B projecting from the first portion 10 may be a portion projecting not only from all (the entire periphery) at positions surrounding the first portion 10 but from a portion of the first portion 10. In addition, the feeding point and a feeding conductor pattern may be single. In addition, the base material layers 9 on which the feeding conductor patterns 30A and 30B are formed may be thinner than the base material layers 9 on which the conductor pattern 45 as the radiation element is formed. In addition, the second portion 20A projects in the Z direction, which forms a hollow portion below the second portion 20A, and this hollow portion may be filled with a resin.

According to the present example embodiment, the following advantageous effects are obtained.
(a) The hollow portion is provided between the conductor pattern 64G as the ground conductor layer, and the conductor pattern 45 as the radiation element, which makes it possible to reduce electrostatic capacitance between the radiation element and the ground conductor, and thus enlarge the radiation element accordingly and enhance an antenna gain.
(b) The hollow portion is provided between the feeding conductor patterns 30A and 30B, and the conductor pattern 64G as the ground conductor layer, and a hollow space (air) has a lower dielectric constant than the base material layers 9, so that an electromagnetic coupling coefficient between the conductor pattern 30A and the conductor pattern 30B is able to be reduced. Accordingly, isolation of two signals of which polarization planes are different is able to be enhanced. In addition, the effect is further increased by thinning the base material layers 9 on which the feeding conductor patterns 30A and 30B are formed.
(c) The periphery of the second portion 20A is surrounded by the first portion 10, which increases mechanical strength of the second portion 20A. Furthermore, the rigidity increases, so that the conductor pattern 45 as the radiation element is able to be defined as predetermined antenna characteristics.
(d) The hollow portion is filled with the resin of a low dielectric constant, which is able to further increase the rigidity of the multilayer substrate 116.
(e) When the hollow portion is filled with a resin of a high dielectric constant, the conductor pattern 45 as the radiation element for obtaining a predetermined resonant frequency is able to be miniaturized, so that a small multilayer substrate 116 and a small electronic device 212 are obtained.

A twelfth example embodiment exemplifies an electronic device including a multilayer substrate in which a conductor pattern for electromagnetic shielding is formed.

FIG. 20 is a perspective view of a multilayer substrate 117A according to the twelfth example embodiment. FIG. 21 is a cross-sectional view taken along a dashed-dotted line in FIG. 20.

As shown in FIG. 20, the multilayer substrate 117A includes a first portion 10 and second portions 20A and 20B. As with the example described in the eleventh example embodiment, the plane shape of the second portion 20A is a rectangular or substantially rectangular shape with rounded corner portions, and the plane shape of the second portion 20B is a rectangular ring shape with rounded corner portions at an inner periphery.

In addition, as with the example described in the eleventh example embodiment, the front surface of the first portion 10 is a convex curved surface, and the back surface of the first portion 10 is a concave curved surface that faces the convex curved surface and gives the thickness to the multilayer substrate 117A.

A conductor pattern 45 as a radiation element (a patch antenna) is formed on an outer surface of the base material layers 9 of the second portion 20A. In addition, conductor patterns 33 and 34 as wiring conductor patterns are formed in the inner layer of the base material layers 9 of the second portions 20A and 20B and the first portion 10. One end of the conductor pattern 33 is connected to the conductor pattern 45 through an interlayer connection conductor.

As shown in FIG. 21, a conductor pattern 49 is formed on an inner surface of the base material layers 9. This conductor pattern 49 is formed as a ground conductor layer. In FIG. 21, a dashed line shows that the conductor pattern 49 is present between the conductor pattern 34 and the conductor pattern 45. With this structure, the conductor pattern 49 significantly reduces interference between a radiation element and a signal line. In addition, the conductor pattern 49, the conductor pattern 33, and the base material layers 9 that is present between the conductor patterns configure a microstrip line. Similarly, the conductor pattern 49, the conductor pattern 34, and the base material layers 9 that is present between the conductor patterns configure a microstrip line.

FIG. 22 is a perspective view of a multilayer substrate 117B according to the twelfth example embodiment. The upper portion of FIG. 23 is a cross-sectional view taken along a dashed-dotted line A-A in FIG. 22, and the lower portion of FIG. 23 is a cross-sectional view taken along a dashed-dotted line B-B in FIG. 22.

In the example shown in FIG. 22, a slot 45S is formed in the conductor pattern 45. In other words, the conductor pattern 45 and the base material layers 9 configure a slot antenna. A conductor pattern 84 is formed in the inner layer of the base material layers 9, and this conductor pattern 84, the conductor patterns 45 and 49 as ground conductor layers and the base material layers 9 configure a stripline. This stripline functions as a feed line to the slot antenna.

According to the present example embodiment, a portion of a stacked-layer substrate is able to be used as a microstrip line or a stripline, a transmission line of a signal need not be separately provided, and an integrated electronic device is obtained.

A thirteenth example embodiment exemplifies a multilayer substrate that is different in the shape of a first portion from the multilayer substrate described above, and an electronic device including such a multilayer substrate.

FIG. 24 is a perspective view of an electronic device 213 configured by a multilayer substrate 118 according to the thirteenth example embodiment and an electronic component 62 mounted on the multilayer substrate.

The multilayer substrate 118 is configured by a first portion 10 and a second portion 20. The first portion 10 and the second portion 20 have a plate shape with a fixed thickness. The front and back surfaces of the first portion 10 are not surfaces that curve around an axis in the projecting direction as in a cylindrical surface, but a portion of a lateral surface of a circular or substantially circular cone. The second portion 20 has a circular or substantially circular plate shape or an elliptical plate shape, and the front surface is a plane.

As shown in the present example embodiment, the front and back surfaces of the first portion 10 of the multilayer substrate 118 need not be limited to a portion of a sphere or ellipsoid, but may be any curved surfaces.

A fourteenth example embodiment shows an example in which a conductor pattern formed in a first portion and second portion of a multilayer substrate is different from the examples described above. The multilayer substrate according to the fourteenth example embodiment is a multilayer substrate in which a conductor pattern for electromagnetic shielding is formed.

The upper portion of FIG. 25 is a perspective view of an electronic device 214 configured by a multilayer substrate 119 according to the fourteenth example embodiment and the electronic component 62 mounted on the multilayer substrate.

The multilayer substrate 119 is configured by a first portion 10 and a second portion 20. The first portion 10 and the second portion 20 have a plate shape with a fixed thickness. The shape of the first portion 10 and the second portion 20 is the same as the example shown in FIG. 24.

The lower portion of FIG. 25 is a cross-sectional view taken along a dashed-dotted line in the upper portion of FIG. 25.

The electronic device 214 is mounted to a not-shown circuit board. The conductor pattern 34 is formed in an inner layer of the first portion 10. In addition, the conductor pattern 33 is formed in those inner layers, from the first portion 10 to the second portion 20. The conductor pattern 34 is a signal line of a transmission signal. The conductor pattern 33 is a signal line of which the one end is electrically connected to a terminal electrode of the electronic component 62 and the other end is electrically connected to a terminal electrode of a circuit board.

The conductor pattern 49 as the ground conductor is formed on the inner surface of the first portion 10 and the second portion 20 or near the inner surface. The conductor pattern 49 is present between the conductor pattern 33 and the conductor pattern 34. With this structure, the conductor pattern 49 electromagnetically shields the conductor pattern 33 and the conductor pattern 34. In other words, interference between the conductor pattern 33 and the conductor pattern 34 is significantly reduced. In addition, the conductor pattern 49, the conductor pattern 33, and the base material layers 9 configure a microstrip line. Similarly, the conductor pattern 49, the conductor pattern 34, and the base material layers 9 configure a microstrip line. It is to be noted that, in a case in which a portion of the conductor pattern 34 functions as a radiation element, the conductor pattern 49 may not be (the ground conductor pattern may be opened) in a region facing the radiation element.

The front surface of the first portion 10 is a convex curved surface PS, and the back surface of the first portion 10 is a concave curved surface DS that faces the convex curved surface PS and gives the thickness to the multilayer substrate 119. In the inner space of this concave curved surface DS, the conductor pattern 49 functions as an electromagnetic shielding conductor for a circuit board, or an electronic component mounted on the circuit board, for example. In other words, the conductor pattern 49 is not only a ground conductor layer of the microstrip line, but electromagnetically shields the circuit board that is present on an inner side of the concave portion formed by the concave curved surface DS or the electronic component mounted on the circuit board.

FIG. 26 is a view showing another multilayer substrate 120 according to the fourteenth example embodiment.

The upper portion of FIG. 26 is a perspective view showing a structure inside the first portion 10, and the lower portion of FIG. 26 is a cross-sectional view taken along a dashed-dotted line in the upper portion of FIG. 26.

The conductor pattern 34 is formed in the inner layer of the first portion 10. In addition, the conductor pattern 33 is formed in those inner layers, from the first portion 10 to the second portion 20. The conductor pattern 34 is a signal line of a transmission signal or a radiation element.

In this manner, the first portion, even when having a cylinder shape, is similarly applicable to the present invention.

A fifteenth example embodiment shows an example in which a conductor pattern formed in a first portion and second portion of a multilayer substrate is different from the examples described above.

The upper portion of FIG. 27 is a perspective view of a multilayer substrate 121 according to the fifteenth example embodiment, and the lower portion of FIG. 27 is a vertical cross-sectional view in a position shown by a dashed-dotted line of the upper portion of FIG. 27.

As shown in FIG. 27, the multilayer substrate 121 includes a first portion 10 and second portions 20A and 20B. As with the example described in the twelfth example embodiment, the plane shape of the second portion 20A is a rectangular or substantially rectangular shape with rounded corner portions, and the plane shape of the second portion 20B is a rectangular ring shape with rounded corner portions at an inner periphery.

In addition, as with the example described in the twelfth example embodiment, the front surface of the first portion 10 is a convex curved surface, and the back surface of the first portion 10 is a concave curved surface that faces the convex curved surface and gives the thickness to the multilayer substrate 121.

Conductor patterns 81 and 82 as wiring patterns is inside the base material layers 9 of the second portion 20A. In addition, the conductor pattern 49 as the ground conductor is formed on the inner surface of the first portion 10 and the second portions 20A and 20B or near the inner surface. This conductor pattern 49, the conductor patterns 81 and 82, and the base material layers 9 each configure a microstrip line.

In the inner space of the concave curved surface DS, the conductor pattern 49 functions as an electromagnetic shielding conductor for a circuit board, or an electronic component mounted on the circuit board, for example. In other words, the conductor pattern 49 is not only a ground conductor layer of the microstrip line, but electromagnetically shields the circuit board that is present in the concave portion or the electronic component mounted on the circuit board.

A sixteenth example embodiment exemplifies various examples of arrangement of a conductor pattern as a signal line or a conductor pattern as a ground conductor layer that is formed in a first portion and second portion of a multilayer substrate.

The drawings shown in FIG. 28 to FIG. 31 are cross-sectional views of each multilayer substrate according to the sixteenth example embodiment.

The three cross-sectional views shown in FIG. 28 are cross-sectional views at positions passing the first portion 10 and second portion 20A of the multilayer substrate.

In the upper portion of FIG. 28, a dashed double-dotted line shows a boundary surface between the first portion 10 and the second portion 20A. In this example, the conductor pattern 82 as a signal line is formed in the second portion 20A, and the conductor pattern 81 as a signal line is formed in the first portion 10. The conductor pattern 49 significantly reduces interference between the conductor pattern 81 and the conductor pattern 82. In this manner, the conductor pattern 82 as the signal line may be formed in the second portion 20A used as a top surface.

In the example shown in the middle portion of FIG. 28, the conductor pattern 83 as the ground conductor is formed between the conductor pattern 81 as the signal line, and the conductor pattern 82, in the same layer as the layer of the conductor patterns 81 and 82. According to this structure, even when the conductor pattern 49 as the ground conductor layer has a partial defect, the conductor pattern 83 functions as a ground conductor layer. In addition, the conductor pattern 83 may increase structural strength of a bent portion, which significantly reduces the defect of the conductor pattern 49. In addition, the conductor pattern 49 formed in the inner layer of the base material layers 9 significantly reduces the interference between the conductor pattern 81 and the conductor pattern 82.

In the example shown in the lower portion of FIG. 28, the conductor pattern 83 as the ground conductor is formed between the conductor patterns 81 and 82 as the signal lines, and an interlayer connection conductor 53 that electrically connects this conductor pattern 83 as the ground conductor and the conductor pattern 49 as the ground conductor is formed. In this manner, the conductor pattern as the ground conductor inside the base material layers 9 and the ground conductor layer spreading on or near the surface of the base material layers 9 may be electrically connected to each other.

In the drawings shown in the upper portion and middle portion of FIG. 29, the first portion 10 has a cylinder-shaped portion and the second portion 20 has a plane-shaped portion. In the example shown in the upper portion of FIG. 29, conductor patterns 81A and 81B as signal lines are formed in the first portion 10 at positions so as to interpose the conductor pattern 49 as the ground conductor layer. In this manner, in the cross-sectional view, the conductor patterns 81A and 81B as the signal lines may be respectively located at the positions corresponding to different side surfaces. The conductor pattern 49 significantly reduces interference between the conductor pattern 81A and the conductor pattern 81B.

In the drawing shown in the middle portion of FIG. 29, a dashed line shows a boundary between layers of the plurality of base material layers 9. The conductor patterns 81 and 82 as the signal lines, although each being formed in the base material layers 9, are formed in different layers. In this manner, the conductor patterns 81 and 82 may be formed in mutually different layers of the base material layers 9.

In the drawing shown in the lower portion of FIG. 29, a dashed double-dotted line shows a boundary surface between the first portion 10 and the second portions 20A and 20C. The conductor pattern 83 as the signal line is formed in the first portion 10, and the conductor pattern 81 as the signal line is formed in the second portion 20C, respectively.

FIG. 30 shows one example of a multilayer substrate including the conductor patterns 81 and 82 as the signal lines, and conductor patterns 49A and 49B as two-layer ground conductor layers that interpose the conductor patterns in a stacking direction. This multilayer substrate includes the conductor pattern 81 as the signal line inside the base material layers 9 of the first portion 10, and the conductor pattern 82 as the signal line inside the base material layers 9 of the second portion 20. The conductor pattern 49A as the ground conductor layer is formed on the inner surface of the base material layers 9, and the conductor pattern 49B as the ground conductor layer is formed on the outer surface of the base material layers 9, respectively. The conductor patterns 81 and 82 are arranged between the conductor patterns 49A and 49B.

In this manner, the conductor pattern 49B as the ground conductor layer is provided, which electromagnetically shields the conductor patterns 81 and 82 as the signal lines from external noise. In addition, radiation of the noise from conductor patterns 81 and 82 to the outside is significantly reduced. It is to be noted that the conductor pattern 49A significantly reduces the interference between the conductor pattern 81 and the conductor pattern 82.

The conductor patterns 49A and 49B, the conductor patterns 81 and 82, and the base material layers 9 each configure a stripline.

FIG. 31 is a view showing some examples of a position at which a conductor pattern as a ground conductor layer is formed.

In the example shown in the drawing of the upper portion of FIG. 31, the conductor pattern 49A as the ground conductor layer on the inner side is formed not on the inner surface of the base material layers 9 but inside the base material layers 9 near the inner surface.

In the example shown in the drawing of the middle portion of FIG. 31, the conductor pattern 49B as the ground conductor layer on the outer side is formed not on the outer surface of the base material layers 9 but inside the base material layers 9 near the outer surface.

In the example shown in the drawing of the lower portion of FIG. 31, the conductor pattern 49A as the ground conductor layer on the inner side is inside the base material layers 9 near the inner surface. In addition, the conductor pattern 49B as the ground conductor layer on the outer side is inside the base material layers 9 near the outer surface.

It is to be noted that, although the example shown in FIG. 31 shows an example in which the conductor pattern 49A, the conductor pattern 49B, or both are provided inside (on the inner layer of) the base material layers 9, the conductor pattern 49A, the conductor pattern 49B, or both may be in a non-exposed state by covering an exposed surface of the conductor patterns 49A and 49B with a resist film.

A seventeenth example embodiment exemplifies an electronic device on which an electronic component is mounted at the second portion.

FIG. 32 is a cross-sectional view of a main portion of an electronic device 215 shown in the seventeenth example embodiment. Conductor patterns 30A and 30B as signal lines are inside the base material layers 9, and a conductor pattern 49 as a ground conductor layer is formed on the inner surface of the base material layers 9. The electronic component 65 is mounted on the upper surface of the second portion 20B.

According to the present example embodiment, interference between the conductor pattern 30A, the conductor pattern 30B, and the electronic component 65 is significantly reduced by the conductor pattern 49. In addition, the conductor pattern 49 electromagnetically shields the circuit board that is present on the inner side of the concave portion formed by the concave curved surface DS or the electronic component mounted on the circuit board.

An eighteenth example embodiment exemplifies a multilayer substrate with a rib, and an electronic device including such a multilayer substrate.

The upper portion of FIG. 33 is a perspective view of an electronic device 216 according to the eighteenth example embodiment, the middle portion of FIG. 33 is a vertical cross-sectional view of a multilayer substrate 122 taken along line X-X of the upper portion of FIG. 33, and the lower portion of FIG. 33 is a vertical cross-sectional view of the multilayer substrate 122 taken along line Y-Y of the upper portion of FIG. 33.

As shown in the upper portion of FIG. 33, the electronic device 216 includes the multilayer substrate 122, and electronic components 69A and 69B mounted on the multilayer substrate 122. The multilayer substrate 122 includes base material layers 9 and a conductor pattern.

As shown in the upper portion and middle portion of FIG. 33, in the multilayer substrate 122, a portion of the second portion 20 (a large portion in this example) forms a plane portion that expands planarly, and the first portion 10 forms a rib 8 that projects from the plane portion.

The rib 8 is formed as a portion of the multilayer substrate 122 by a drawing process of the base material layers 9 by a thermoplastic resin.

The rib 8 forms a closed loop surrounding the plane portion, when viewed in the stacking direction (the Z direction) of the base material layers 9 of the second portion 20. In this example, two rectangular closed loops are adjacent to each other.

As shown in the middle portion and lower portion of FIG. 33, the multilayer substrate 122 includes a conductor pattern 81 as a signal line, and conductor patterns 49A and 49B as two-layer ground conductor layers that interpose the conductor pattern in the stacking direction. The conductor pattern 81 as the signal line is patterned in a direction orthogonal to an extension direction of the rib 8. In addition, the conductor pattern 83 as the ground conductor layer is formed in the same layer as the layer of this conductor pattern 81 as the signal line. Then, the conductor patterns 49A and 49B are connected to this conductor pattern 83 through the interlayer connection conductor 53.

The conductor pattern 81 as the signal line, the conductor patterns 49A and 49B as the two-layer ground conductor layers that interpose the conductor pattern in the stacking direction, and the base material layers 9 between the conductor patterns 49A and 49B and the conductor pattern 81 configure a triplate stripline.

According to the present example embodiment, the rigidity of the multilayer substrate 122 is increased by projection of the rib 8 of the closed loop, and plane-shaped stability of the multilayer substrate 122 and the electronic device 216 is high. In addition, the rib 8 also includes the conductor pattern 81 as the signal line, the conductor patterns 49A and 49B as the ground conductor layers, the conductor pattern 83, and the interlayer connection conductor 53, so that the rigidity-improving effect by the rib 8 is high.

FIG. 34 shows plan views of several other multilayer substrates according to the eighteenth example embodiment. As shown in (1) in this FIG. 34, the closed loop of the rib 8 may be single. In addition, as shown in (2), the closed loop may be three or more. In addition, as shown in (3), the rib 8 not only forms the closed loop but may have a portion extending inward toward the closed loop. In addition, as shown in (4) and (5), the rib 8 may be configured by one rib that forms the closed loop and a different rib independent of such a rib.

The extension direction of the rib 8 is not limited to the direction orthogonal to each other, and, as shown in (6), (7), and (8), may include a rib extending to a non-orthogonal direction.

The upper portion and lower portion of FIG. 35 are cross-sectional views of the other multilayer substrates according to the eighteenth example embodiment. The cross-sectional positions of these cross-sectional portions correspond to the cross-sectional positions of the cross-sectional views shown in the middle portion and lower portion in FIG. 33. In the example shown in FIG. 35, a conductor pattern 81 as a signal line, and a conductor pattern 49 as a one-layer ground conductor layer are provided. The conductor pattern 81 as the signal line, the conductor pattern 49 as the ground conductor layer, and the base material layers 9 between the conductor pattern 49 and the conductor pattern 81 configure a microstrip line.

In this manner, a transmission line orthogonal to the extension direction of the rib 8 may be a microstrip line.

FIG. 36 shows cross-sectional views of several other multilayer substrates according to the eighteenth example embodiment. The cross-sectional positions of these cross-sectional views correspond to the cross-sectional positions of the cross-sectional views shown in the middle portion of FIG. 33.

As shown in (1) in FIG. 36, the conductor pattern as the signal line does not necessarily need to be formed in the rib. In addition, as shown in (2), the conductor pattern may be formed only on the outer surface of the rib. Similarly, as shown in (3), the conductor pattern may be formed only on an inner side of the rib. In addition, as shown in (4), the conductor patterns 81A and 81B as signal lines may be patterns extending in the extension direction of the rib. In addition, as shown in (5) and (6), the conductor patterns 49A and 49B as the ground conductor layers may be formed on the lower surface of the base material layers 9, and the conductor pattern 81 as the signal line extending in the extension direction of the rib may be formed. This structure may be used as a coplanar waveguide. In addition, as shown in (7), the conductor patterns 49A and 49B as ground conductor layers are formed on the inner surface of the rib, and the conductor patterns 49A and 49B as external electrodes may be formed on the lower surface of the second portion. In addition, as shown in (8), the conductor patterns 81A, 81B, and 81C as signal lines are formed in the inner layer of the rib, and the conductor pattern 49 as the ground conductor layer may be formed on the lower surface of the base material layers 9. This structure may configure three microstrip lines each extending in the extension direction of the rib.

According to the present example embodiment, when the ground conductor layers are connected by the interlayer connection conductor, loss due to unwanted resonance and unwanted radiation of electromagnetic waves is able to be significantly reduced. In addition, both ends of the signal line are drawn out to the outer layer by the interlayer connection conductor, which makes it possible to easily connect a connector, a chip component, an IC, or the like. In addition, it is also easy to connect other transmission lines by solder or the like.

A nineteenth example embodiment exemplifies a multilayer substrate in which a transmission path is provided at the first portion, or from the first portion to the second portion, and an electronic device including such a multilayer substrate.

The upper portion of FIG. 37 is a plan view of an electronic device 217 including a multilayer substrate 123 and electronic components 62 and 65, and the lower portion of FIG. 37 is a vertical cross-sectional view taken along a dashed-dotted line in the upper portion.

The upper portion of FIG. 38 is a partial cross-sectional view of the electronic device 217. Herein, for the sake of clarity of the drawings, hatching of the base material layers 9 is omitted. The lower portion of FIG. 38 is a transverse cross-sectional view taken along a dashed-dotted line in the upper portion of FIG. 38. In this drawing as well, for the sake of clarity of the drawings, the hatching of the base material layers 9 is omitted.

In the base material layers 9, the conductor pattern 49 as the ground conductor layer, the conductor pattern 81 as the signal line, and mainly the base material layers 9 between the conductor patterns configure a microstrip line MSL at two locations. In addition, a conductor pattern 80 that faces a location of the conductor pattern 81 spreading in a layer direction is formed. Between this conductor pattern 80 and the conductor pattern 81, a plurality of interlayer connection conductors 53 that electrically connect the conductor pattern 80 and 81 each other in the stacking direction of the base material layers 9 are located at positions arranged in the layer direction while maintaining a predetermined width. The conductor patterns 80 and 81, the plurality of interlayer connection conductors 53, and the base material layers 9 between the conductor patterns 80 and 81, and the plurality of interlayer connection conductors 53 configure a waveguide. An interval between the conductor patterns 81 and 82 is smaller enough than a half wavelength, which uses the TE10 mode as a propagation mode. When the interval between the interlayer connection conductors 53 is smaller enough than a single wavelength (approximately 1/10 of a wavelength or less), the electromagnetic waves of the TE mode are able to be propagated without radiating outward. This waveguide is able to be called a SIW (substrate integrated waveguide).

The microstrip line MSL and the waveguide SIW are coupled with each other, so that a propagation signal propagates the microstrip line MSL as the electromagnetic waves of the TEM mode, and propagates the waveguide SIW as the electromagnetic waves of the TE mode.

The electronic component 65 shown in the upper portion of FIG. 38 is a chip antenna. In addition, the electronic component 62 is an IC (a semiconductor element for antennas) for communication that performs transmission and/or reception of a communication signal by use of the antenna.

As shown in the transverse cross-sectional view in the lower portion of FIG. 38, at a connection portion between the microstrip line MSL and the waveguide SIW, the conductor pattern 81 in the range of the microstrip line MSL is made into a tapered shape, which enhances the matching between the characteristic impedance of the microstrip line MSL and the characteristic impedance of the waveguide.

According to the present example embodiment, the waveguide SIW that connects the antenna and the IC is made into a bent shape at a three-dimensional curve-shaped portion of the multilayer substrate 123. Accordingly, the degree of freedom in arrangement and wiring design of each portion is able to be improved.

FIG. 39 is a plan view of another electronic device according to the nineteenth example embodiment. In the example shown in the upper portion of FIG. 39, the electronic component 65 as eight chip antennas is mounted at the projecting portion of the multilayer substrate. In addition, in the example shown in the lower portion of FIG. 39, the electronic component 65 as six chip antennas is mounted at the projecting portion of the multilayer substrate. In this manner, a plurality of chip antennas of which each orientation is different may be arranged.

In the example shown in the lower portion of FIG. 39, an IC 62 mounted at the second portion of the multilayer substrate is shown. Between the electronic component 65 as each chip antenna and the IC 62 (the semiconductor element for antennas), the microstrip line MSL and the waveguide SIW that have been already shown are preferably arranged so that a signal may propagate in a path of approximately the shortest distance, which is possible in the present example embodiment.

It is to be noted that a conductor pattern as a patch antenna may be formed on the multilayer substrate in addition to the structure of mounting the electronic component 65 as the chip antenna on the multilayer substrate.

A twentieth example embodiment exemplifies an electronic device including a slot antenna.

The upper portion of FIG. 40 is a plan view of an electronic device 218 including a multilayer substrate 124 and the electronic component 62, and the lower portion of FIG. 40 is a vertical cross-sectional view taken along a dashed-dotted line in the upper portion.

The upper portion of FIG. 41 is a partial cross-sectional view of the electronic device 218. Herein, for the sake of clarity of the drawings, the hatching of the base material layers 9 is omitted. The middle portion of FIG. 41 is a transverse cross-sectional view taken along a dashed-dotted line in the upper portion in the drawing of the upper portion of FIG. 41, and the lower portion of FIG. 41 is a transverse cross-sectional view taken along a dashed-dotted line in the lower portion in the drawing of the upper portion of FIG. 41. In these drawings as well, for the sake of clarity of the drawings, the hatching of the base material layers 9 is omitted.

In the base material layers 9, the conductor pattern 49 as the ground conductor layer, the conductor pattern 81 as the signal line, and mainly the base material layers 9 between the conductor patterns configure a microstrip line MSL. In addition, the conductor pattern 80 that faces a location of the conductor pattern 81 spreading in a layer direction is formed. Between this conductor pattern 80 and the conductor pattern 81, a plurality of interlayer connection conductors 53 that electrically connect the conductor pattern 80 and 81 each other in the stacking direction of the base material layers 9 are located at positions arranged in the layer direction while maintaining a predetermined width. The conductor patterns 80 and 81, the plurality of interlayer connection conductors 53, and the base material layers 9 between the conductor patterns 80 and 81, and the plurality of interlayer connection conductors 53 configure the waveguide SIW. An aperture AP is formed in the conductor pattern 80 at an upper portion of this waveguide SIW. A conductor pattern 84 is located at the upper portion of the conductor pattern 80, and the conductor pattern 80 and the conductor pattern 84 are electrically connected through an interlayer connection conductor.

The electronic device 218 includes a housing 72 made of metal. An opening 72S is formed in this housing 72. This opening 72S functions as a radiator of the slot antenna.

It is to be noted that, although, in the above-described example, the opening 72S for functioning as the slot antenna in the housing 72 is provided, not only a housing but a case in which a cover member is provided is similarly applied. In other words, in a case in which a metal cover is arranged on the upper surface of the multilayer substrate 124, a slot may be formed in the metal cover.

A twenty-first example embodiment exemplifies an electronic device including various antennas.

FIG. 42 shows perspective views of electronic devices 219 and 220 according to the twenty-first example embodiment. The electronic device 219 shown in the upper portion of FIG. 42 is configured by a multilayer substrate and a plurality of electronic components 65.

In the electronic device 219, the multilayer substrate includes a first portion 10 and a second portion 20 being continuous with the first portion 10. The first portion 10 has a spherical cap shape. The electronic components 65 are antenna elements, respectively, and are arranged around the spherical cap shape. These plurality of antenna elements configure an array antenna.

The electronic device 220 shown in the lower portion of FIG. 42 is configured by a multilayer substrate and a plurality of electronic components 65. In the electronic device 220, the multilayer substrate includes a first portion 10 and a second portion 20 being continuous with the first portion 10. The first portion 10 and the second portion 20 define a truncated cone shape. The electronic components 65 are antenna elements, respectively, and are arranged around a conical shape. These plurality of antenna elements configure an array antenna.

In the electronic devices 219 and 220, an array antenna of which directivity is isotropic is able to be easily configured. In addition, a curvature of a location in which each antenna element is arranged is constant, which uniformizes stress applied to the interlayer connection conductor located at the first portion 10, so that the reliability is high.

The upper portion of FIG. 43 is a partial cross-sectional view of the first portion 10 of the electronic device 219 shown in the upper portion of FIG. 42, and the lower portion of FIG. 43 is a partial cross-sectional view of the first portion 10 of the electronic device 220 shown in the lower portion of FIG. 42. For example, in a case in which an interlayer connection conductor is located at the first portion 10 after the first portion 10 is formed, as indicated by a straight arrow in FIG. 43, a via hole that results in facing in an oblique direction in the first portion 10 is formed, and thus the interlayer connection conductor is provided by filling the via hole with a conductive material. In contrast, in the present example embodiment, the stress applied to the interlayer connection conductor, as indicated by a dashed-dotted line, is in a direction normal to the inner and outer surfaces of the first portion 10, so that the interlayer connection conductor has a high allowable stress. In other words, the reliability of the interlayer connection conductor against stress is high.

A twenty-second example embodiment exemplifies a multilayer substrate including a first portion having a dome shape of which a portion is cut out.

The upper portion and lower portion of FIG. 44 each are a perspective view and front view of a multilayer substrate 125 according to the twenty-second example embodiment. The upper portion, middle portion, and lower portion of FIG. 45 each are a plan view, bottom view, and side view of the multilayer substrate 125.

The multilayer substrate 125 includes a first portion 10 having a dome shape, and a second portion 20 projecting from a portion of positions surrounding the first portion 10. Specifically, the first portion 10 has a shape in which an end portion of the dome shape on a side in a negative direction of a Y-axis is cut by a plane parallel to a X-Z plane, from a typical dome shape having a circular or substantially circular shape as viewed in the Z direction. The second portion 20 is drawn out outward on a side in a positive direction of the Y-axis of the first portion 10.

A twenty-third example embodiment exemplifies a multilayer substrate including arranged plurality of dome-shaped first portions.

The upper portion and lower portion of FIG. 46 each are perspective views as viewed from an upper side and bottom side of a multilayer substrate 126 according to the twenty-third example embodiment. The upper portion, middle portion, and lower portion of FIG. 47 each are a plan view, bottom view, and side view of the multilayer substrate 126.

The multilayer substrate 126 includes a plurality of dome-shaped first portions 10 that are vertically and horizontally aligned and define a periodic structure, and a rectangular-shaped second portion 20 that surrounds and couples the plurality of first portions 10. The plurality of first portions 10 project out in the same direction from the second portion 20.

For example, the multilayer substrate 126 is used for a touch sensor. In that case, the first portion 10 includes an electrode for detecting electrostatic capacitance, and the second portion 20 includes a circuit pattern.

A twenty-fourth example embodiment exemplifies an electronic device including a multilayer substrate having a thin region in a first portion.

FIG. 48 is a cross-sectional view of an electronic device 221 according to the twenty-third example embodiment.

The electronic device 221, as in the example shown in FIG. 12, includes a circuit board 60, and an electronic component 69 and multilayer substrate 127 that are mounted on the circuit board 60. A conductor pattern 30 functioning as a wiring pattern is formed in an inner layer of the multilayer substrate 127. A terminal electrode 42 connected to the conductor pattern 30 is located at an end portion of the multilayer substrate 127. The multilayer substrate 127 includes a first portion 10 having a dome shape, and a second portion 20 projecting from positions surrounding the first portion 10. The first portion 10 has a thin region 25 that is thinner than other regions of the multilayer substrate 127 so as to avoid an electronic component 69 arranged on an inner side of the first portion 10. The thin region 25 is provided at the upper portion of the first portion 10.

A twenty-fifth example embodiment exemplifies a multilayer substrate including a notch portion.

The upper portion and lower portion of FIG. 49 each are perspective views as viewed from an upper side and bottom side of a multilayer substrate 128 according to the twenty-fifth example embodiment. The upper portion, middle portion, and lower portion of FIG. 50 each are a front view, right side view, and left side view of the multilayer substrate 128. FIG. 51 is a plan view showing the multilayer substrate 128 arranged in a housing 73.

The multilayer substrate 128 includes an upper-surface portion 14, a side-surface portion 15 provided so as to surround the upper-surface portion 14 along an edge of the upper-surface portion 14, and a bottom-surface portion 16 provided so as to surround the side-surface portion 15. The multilayer substrate 128 has a first portion 10 at a corner portion formed by the side-surface portion 15, and at a corner portion formed by the upper-surface portion 14 and the side-surface portion 15. The multilayer substrate 128 has a second portion 20A at the upper-surface portion 14, and a second portion 20B at the bottom-surface portion 16. Moreover, the multilayer substrate 128 has a notch portion 17 provided so as to avoid a projection 74 of the housing 73. Specifically, the notch portion 17 is provided on the side in the positive direction of an X axis of the multilayer substrate 128. The upper-surface portion 14, when viewed in the Z direction, has a rectangular or substantially rectangular shape in which a recess 18 is provided on the side in the positive direction of the X axis. The side-surface portion 15 surrounds the upper-surface portion 14 along the edge of the upper-surface portion 14 other than the edge of the recess 18.

Finally, the present invention is not limited to the foregoing example embodiments. Various modifications or changes can be appropriately made by those skilled in the art. The scope of the present invention is defined not by the foregoing example embodiments but by the following claims. Furthermore, the scope of the present invention is intended to include all possible modifications or changes from the example embodiments within the scopes of the claims and the scopes of equivalents.

For example, although, in each of the above-described example embodiments, except for FIG. 3, the thickness of the first portion and second portion of the multilayer substrate is uniform, for both the first portion and the second portion, the thickness may vary depending on the region. In addition, the first portion and the second portion may be different in thickness.

In addition, although FIG. 1, FIG. 7, FIG. 15, and FIG. 16, for example, show the examples in which a circuit element such as an antenna element and a coil element is located at the first portion of the multilayer substrate, a circuit element by a conductor pattern may be configured at the second portion of the multilayer substrate.

In addition, although some electronic devices described above show the example in which the conductor pattern located at the first portion 10 is connected to the circuit board or the electronic component through the conductor pattern located at the second portion 20, the conductor pattern located at the first portion 10 may be structured to be directly connected to the circuit board or the electronic component.

In addition, in each of the above-described example embodiments, the plane shape of the multilayer substrate as viewed in the projecting direction of the multilayer substrate by existence of the convex curved surface PS and concave curved surface DS of the multilayer substrate, although being an approximate circular or substantially circular shape or an approximately quadrilateral shape, as shown in FIG. 52, for example, may be a hexagon, a triangle, a polygon partially having a recess, a shape partially having roundness, or the like. Accordingly, it is also possible to increase the degree of freedom in mounting onto a circuit board or assembling into a housing.

In addition, although the nineteenth example embodiment and the twentieth example embodiment, for example, show the example in which the microstrip line is used as a portion of a feeding transmission line, the triplate stripline may be configured as a feeding transmission line.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A multilayer substrate comprising:
a plurality of base material layers and a conductor pattern stacked on each other;
a first portion; and
a second portion; wherein
front and back surfaces of the second portion are planes;
a same layer of the base material layers is provided across the first portion and the second portion;
at least a portion of the conductor pattern is provided across the first portion and the second portion, in an inside of the multilayer substrate;
in the first portion, the conductor pattern is directly in contact with the base material layers; and
the first portion has a dome shape.

2. The multilayer substrate according to claim 1, wherein a shape of the second portion as viewed in a stacking direction of the base material layers of the second portion includes a shape projecting from all or a portion of positions surrounding the first portion.

3. The multilayer substrate according to claim 2, wherein a notch or an opening is located in the second portion of the multilayer substrate.

4. The multilayer substrate according to claim 1, wherein
the first portion includes a circuit portion including the base material layers and the conductor pattern; and
the second portion includes a transmission line including the base material layers and the conductor pattern and being connected to the circuit portion.

5. The multilayer substrate according to claim 1, wherein an outer shape of the second portion as viewed in a stacking direction of the base material layers of the second portion is circular or substantially circular.

6. The multilayer substrate according to claim 1, wherein
the first portion includes a first transmission line including the conductor pattern as a signal line and the base material layers;
the second portion includes a second transmission line including the conductor pattern as a signal line and the base material layers;
the conductor pattern as a ground conductor layer is located on a back surface of the first portion and the second portion or adjacent to the back surface;
the base material layers, in the first portion, are bent toward a back surface of the base material layers; and
the conductor pattern as the ground conductor layer located on the back surface of the first portion and the second portion or near the back surface is positioned between the conductor pattern as the signal line of the first transmission line and the conductor pattern as the signal line of the second transmission line so as to overlap with the conductor pattern as the signal line of the first transmission line and the conductor pattern as the signal line of the second transmission line.

7. The multilayer substrate according to claim 6, wherein the conductor pattern as the ground conductor layer includes the conductor pattern as the ground conductor layer that faces the conductor pattern as the signal line in a thickness direction of the base material layers and the conductor pattern as the ground conductor layer along an identical base material layer among the plurality of base material layers.

8. The multilayer substrate according to claim 1, wherein a material of the base material layers is a thermoplastic resin.

9. The multilayer substrate according to claim 1, wherein the conductor pattern inside the first portion of the multilayer substrate includes a connection conductor defining a conductive path in a direction of the stacking.

10. The multilayer substrate according to claim 1, wherein, with reference to a plurality of cross-sections passing through a boundary between the first portion and the second portion, a minimum angle defined by the first portion and the second portion at the boundary is an obtuse angle.

11. The multilayer substrate according to claim 1, wherein the second portion includes a region in which a thickness of the second portion is smaller than a thickness of the first portion.

12. The multilayer substrate according to claim 1, wherein the first portion includes a plurality of first portions.

13. The multilayer substrate according to claim 1, wherein a circuit element or a wiring pattern by the conductor pattern is included in the first portion.

14. The multilayer substrate according to claim 13, wherein the wiring pattern includes a radiation conductor at the second portion.

15. The multilayer substrate according to claim 13, wherein the conductor pattern defines a radiation element or a slot antenna.

16. The multilayer substrate according to claim 15, wherein
the base material layers, in the first portion, are bent toward a back surface of the base material layers; and
a semiconductor element for an antenna that is electrically connected to the conductor pattern for the radiation element or that is connected to the slot antenna by the conductor pattern defining the slot antenna is arranged at or adjacent to the back surface of the base material layers.

17. The multilayer substrate according to claim 1, wherein
the conductor pattern in the first portion includes two planar conductors extending in a layer direction of the plurality of base material layers, and a plurality of interlayer connection conductors electrically connecting the planar conductors in a stacking direction of the base material layers at positions at which the two planar conductors are arranged while maintaining a predetermined width in the layer direction; and
the planar conductors, the plurality of interlayer connection conductors, and the base material layers between the planar conductors and the plurality of interlayer connection conductors define a waveguide.

18. The multilayer substrate according to claim 17, wherein
the conductor pattern in the first portion includes a conductor pattern as a ground conductor layer expanding in the layer direction of the plurality of base material layers, and a conductor pattern as a signal line arranged to face the conductor pattern as the ground conductor layer;
the conductor pattern as the ground conductor layer, the conductor pattern as the signal line, and the base material layers between the conductor pattern as the ground conductor layer and the conductor pattern as the signal line define a stripline; and
the conductor pattern in the first portion is connected to the conductor pattern as the signal line, and one of the two planar conductors.

19. The multilayer substrate according to claim 1, wherein a notch-shaped portion is located in the first portion of the multilayer substrate.

20. A method of manufacturing the multilayer substrate according to claim 9, the method comprising:
forming the first portion and the second portion of the multilayer substrate by performing heating and pressing in a state in which the base material layers are stacked; and
filling an opening in the direction of the stacking with conductive paste and performing the heating and pressing, and then forming the conductive paste as the conductive path.

21. An electronic device comprising:
the multilayer substrate according to claim 1; and
a circuit board or an electronic component located on an inner side of a hollow portion defined by the base material layers.

22. The electronic device according to claim 21, wherein the circuit board or the electronic component is connected to the conductor pattern at the second portion of the multilayer substrate or the conductor pattern at the first portion of the multilayer substrate.

23. The electronic device according to claim 22, wherein a through hole is located in the first portion of the multilayer substrate.

24. A multilayer substrate comprising:
a plurality of base material layers and a conductor pattern and configured stacked on each other;
a first portion; and
a second portion; wherein front and back surfaces of the second portion are planes;
a same layer of the base material layers is provided across the first portion and the second portion;
at least a portion of the conductor pattern is provided across the first portion and the second portion, in an inside of the multilayer substrate;
in the first portion, the conductor pattern is directly in contact with the base material layers;
an upper-surface portion, and a side-surface portion provided so as to surround the upper-surface portion along an edge of the upper-surface portion, are provided;
at least a portion of the first portion is bent and provided at the side-surface portion, or at a boundary between the upper-surface portion and the side-surface portion; and
at least a portion of the second portion is provided at the upper-surface portion.

25. The multilayer substrate according to claim 24, wherein, when viewed in a stacking direction of the base material layers of the second portion, at least a portion of the second portion is surrounded by the first portion.

26. The multilayer substrate according to claim 24, wherein
a whole or a portion of the second portion defines a plane portion that expands planarly, and the first portion defines a rib that projects from the plane portion; and
when viewed in a stacking direction of the base material layers of the second portion, the rib defines a closed loop surrounding the plane portion.

27. The multilayer substrate according to claim 26, wherein the conductor pattern is arranged at the first portion.

28. The multilayer substrate according to claim 26, wherein the conductor pattern arranged at the first portion defines a conductor pattern as a signal line, a conductor pattern as a ground conductor layer, and an interlayer connection conductor electrically connected to the conductor pattern as the signal line or the conductor pattern as the ground conductor layer.

29. The multilayer substrate according to claim 24, wherein the second portion includes a portion projecting from a portion surrounding the first portion or a part of the portion surrounding the first portion as viewed in a stacking direction of the base material layers of the second portion, and a portion surrounded by the first portion.

30. A multilayer substrate comprising:
a plurality of base material layers and a conductor pattern stacked on each other;
a first portion; and
a second portion; wherein
front and back surfaces of the second portion are planes;
a same layer of the base material layers is provided across the first portion and the second portion;
at least a portion of the conductor pattern is provided across the first portion and the second portion, in an inside of the multilayer substrate;
in the first portion, the conductor pattern is directly in contact with the base material layers;
the first portion, as viewed in a stacking direction of the base material layers of the second portion, defines a closed loop; and
a cross-section of the first portion perpendicular to a direction along the first portion is bent.
